(19) United States
(12) Patent Application Publication
(10) Pub. No.: US 2017/0117056 A1
(43) Pub. Date: Apr. 27, 2017

(54) MEMORY DEVICE AND AN EDGE WORD LINE MANAGEMENT METHOD THEREOF

(71) Applicant: SAMSUNG ELECTRONICS CO., LTD., SUWON-SI (KR)

(72) Inventors: HYUN-KOOK PARK, ANYANG-SI (KR); YEONG-TAEK LEE, SEOUL (KR); MAKOTO HIRANO, SEONGNAM-SI (KR)

(21) Appl. No.: 15/296,197

(22) Filed: Oct. 18, 2016

(30) Foreign Application Priority Data
Oct. 22, 2015 (KR) 10-2015-0147542

(51) Int. Cl. G11C 16/34; G11C 16/08; G11C 16/28; G11C 16/04; G11C 16/10; G11C 16/16

(52) U.S. Cl. CPC G11C 16/3495; G11C 16/10; G11C 16/16; G11C 16/28; G11C 16/0483; G11C 16/3445; G11C 16/08

(57) ABSTRACT

An edge word line management method includes performing an erase operation on a memory device in response to an erase command, randomly determining data of a dummy pattern, and performing a post-program operation by writing the data of the dummy pattern in a dummy memory cell, wherein the dummy memory cell is adjacent to a main memory cell of a cell string included in a memory block for which the erase operation has been performed.

### CROSS-REFERENCE TO RELATED APPLICATION

This application claims priority under 35 U.S.C. §119 to Korean Patent Application No. 10-2015-0147542, filed on Oct. 22, 2015, in the Korean Intellectual Property Office, the disclosure of which is incorporated by reference herein in its entirety.

### TECHNICAL FIELD

The inventive concept relates to a memory device, and more particularly, to a memory device and an edge word line management method thereof.

### DISCUSSION OF RELATED ART

Memory devices are used to store data and are classified as volatile memory devices and nonvolatile memory devices. In the volatile memory devices, stored data is erased in the absence of power. However, the nonvolatile memory devices maintain stored data in the absence of power. As a type of nonvolatile memory device, a flash memory device may be applied to portable phones, digital cameras, personal digital assistants (PDAs), computing devices, and/or the like.

### SUMMARY

According to an exemplary embodiment of the inventive concept, there is provided an edge word line management method of a memory device that includes performing an erase operation on a memory device in response to an erase command, randomly determining data of a dummy pattern, and performing a post-program operation by writing the data of the dummy pattern in a dummy memory cell, wherein the dummy memory cell is adjacent to a main memory cell of a cell string included in a memory block for which the erase operation has been performed.

According to an exemplary embodiment of the inventive concept, the dummy memory cell is disposed between the main memory cell and a ground selection transistor of the cell string.

According to an exemplary embodiment of the inventive concept, when a plurality of dummy memory cells are disposed between the main memory cell and a ground selection transistor of the cell string included in the memory block, data of the dummy pattern is written in a dummy memory cell closest to the main memory cell.

According to an exemplary embodiment of the inventive concept, randomly determining data of a dummy pattern comprises: determining the data of the dummy pattern as data which is read from an initially set word line of the memory block and backed up before the erase operation.

According to an exemplary embodiment of the inventive concept, randomly determining data of a dummy pattern comprises: determining the data of the dummy pattern as data obtained by inverting some data which is read from an initially set word line of the memory block before the erase operation.

According to an exemplary embodiment of the inventive concept, randomly determining data of a dummy pattern comprises: determining the data of the dummy pattern as one data pattern selected from two or more candidate data patterns by using information generated in a verification process of the erase operation.

According to an exemplary embodiment of the inventive concept, randomly determining data of a dummy pattern comprises: setting at least two candidate data patterns; and determining the data of the dummy pattern as one data pattern selected from the at least two candidate data patterns, based on a phase which is detected at a certain time of one or more clock signals used in the memory device.

According to an exemplary embodiment of the inventive concept, randomly determining data of a dummy pattern comprises: determining the data of the dummy pattern as an even or odd bit line pattern which is randomly set based on a phase detected at a certain time of one or more clock signals used in the memory device by using a connection structure of a bit line and a page buffer.

According to an exemplary embodiment of the inventive concept, the method further comprises: checking a set state of a post-program mode, wherein when the post-program mode is enabled, a post-program operation is performed, and when the post-program mode is disabled, the post-program operation is not performed.

According to an exemplary embodiment of the inventive concept, the method further comprises: when a program or erase cycle count for each of a plurality of memory blocks is greater than an initially set threshold value, setting a corresponding memory block to a post-program mode enable state.

According to an exemplary embodiment of the inventive concept, there is provided an edge word line management method of a memory device that includes randomly determining data of a dummy pattern in response to a program command for performing a first program operation on a free memory block of the memory device, performing a pre-program operation by writing the data of the dummy pattern in a dummy memory cell, wherein the dummy memory cell is adjacent to a main memory cell of a cell string included in the free memory block, and after the pre-program operation is performed, performing a program operation in response to the program command on the main memory cell.

According to an exemplary embodiment of the inventive concept, the dummy memory cell is disposed between the main memory cell and a ground selection transistor of the cell string included in the free memory block.

According to an exemplary embodiment of the inventive concept, randomly determining data of a dummy pattern comprises: determining the data of the dummy pattern as one data pattern selected from at least two candidate data patterns, based on a phase which is detected at a certain time of one or more clock signals.

According to an exemplary embodiment of the inventive concept, the method further comprises: checking a set state of a pre-program mode, wherein when the pre-program mode is enabled, the pre-program operation is performed, and when the pre-program mode is disabled, the pre-program operation is not performed.

According to an exemplary embodiment of the inventive concept, the method further comprises: when a program or erase cycle count for each of a plurality of memory blocks is greater than an initially set threshold value, setting a corresponding memory block to a pre-program mode enable state.

According to an exemplary embodiment of the inventive concept, there is provided a method of operating a memory device that comprises: performing an erase operation on a cell string of the memory device, wherein the cell string includes dummy memory cells and main memory cells; programming data of a dummy pattern in a first dummy memory cell, wherein the first dummy memory cell is adjacent to a first main memory cell; and programming the first main memory cell after the first dummy memory cell is programmed.

According to an exemplary embodiment of the inventive concept, a program management circuit determines the data of the dummy pattern, and wherein the program management circuit is included in the memory device or a memory controller.

According to an exemplary embodiment of the inventive concept, the data of the dummy pattern is random data.

According to an exemplary embodiment of the inventive concept, the first dummy memory cell is disposed between the first main memory cell and a ground select transistor of the cell string.

According to an exemplary embodiment of the inventive concept, the dummy memory cells and the main memory cells are vertically stacked on each other in the cell string.

### BRIEF DESCRIPTION OF THE DRAWINGS

The above and other features of the inventive concept will become more clearly understood by describing in detail exemplary embodiments thereof with reference to the accompanying drawings in which:

FIG. 1 is a block diagram illustrating a memory system according to an exemplary embodiment of the inventive concept;

FIG. 2 is a block diagram illustrating a memory system according to an exemplary embodiment of the inventive concept;

FIG. 3 is a block diagram illustrating a memory system according to an exemplary embodiment of the inventive concept;

FIG. 4 is a block diagram illustrating a memory system according to an exemplary embodiment of the inventive concept;

FIG. 5 is a block diagram illustrating a memory device included in the memory system of FIG. 1 according to an exemplary embodiment of the inventive concept;

FIG. 6 is a block diagram illustrating a memory device included in the memory system of FIG. 2 or 4 according to an exemplary embodiment of the inventive concept;

FIG. 7 is a block diagram illustrating a memory device included in the memory system of FIG. 3 according to an exemplary embodiment of the inventive concept;

FIG. 8 illustrates a memory cell array illustrated in FIGS. 5 to 7 according to an exemplary embodiment of the inventive concept;

FIG. 9 is a circuit diagram illustrating a memory block included in the memory cell array illustrated in FIG. 8 according to an exemplary embodiment of the inventive concept;

FIG. 10 is a circuit diagram illustrating a memory block included in the memory cell array illustrated in FIG. 8 according to an exemplary embodiment of the inventive concept;

FIG. 11 is a cross-sectional view illustrating a memory cell included in the memory block illustrated in FIG. 9 or 10 according to an exemplary embodiment of the inventive concept;

FIG. 12 illustrates a block configuration of a memory controller illustrated in FIG. 1 or 3 according to an exemplary embodiment of the inventive concept;

FIG. 13 illustrates a block configuration of a memory controller illustrated in FIG. 2 according to an exemplary embodiment of the inventive concept;

FIG. 14 illustrates a block configuration of a memory controller illustrated in FIG. 4 according to an exemplary embodiment of the inventive concept;

FIG. 15 shows an initial program state in one cell string included in the memory block illustrated in FIG. 9 or 10 under a condition where a post-program mode or a preprogram mode is disabled according to an exemplary embodiment of the inventive concept;

FIG. 16 shows a threshold voltage variation of word line-based memory cells in a memory block based on program execution under a condition where the post-program mode or the preprogram mode is disabled according to an exemplary embodiment of the inventive concept;

FIGS. 17A-C show an after-erase-operation program process for one cell string included in the memory block illustrated in FIG. 9 or 10 under a condition where the post-program mode or the preprogram mode is disabled according to an exemplary embodiment of the inventive concept;

FIG. 18 shows a threshold voltage variation of word line-based memory cells in a memory block based on program execution under a condition where the post-program mode or the preprogram mode is enabled according to an exemplary embodiment of the inventive concept;

FIG. 19 is a diagram for describing a method of randomly determining data of a dummy pattern used for a post-program operation or a preprogram operation according to an exemplary embodiment of the inventive concept;

FIG. 20 is a diagram for describing a method of randomly determining data of a dummy pattern used for a post-program operation according to an exemplary embodiment of the inventive concept;

FIG. 21 is a diagram for describing a method of randomly determining data of a dummy pattern used for a post-program operation or a preprogram operation according to an exemplary embodiment of the inventive concept;

FIGS. 22A-C are diagrams for describing a method of randomly determining data of a dummy pattern used for a post-program operation according to an exemplary embodiment of the inventive concept;

FIG. 23 illustrates a flowchart of an edge word line management method of a memory device according to an exemplary embodiment of the inventive concept;

FIG. 24 illustrates a flowchart of an edge word line management method of a memory device according to an exemplary embodiment of the inventive concept;

FIG. 25 illustrates a flowchart of an edge word line management method of a memory device according to an exemplary embodiment of the inventive concept;

FIG. 26 illustrates a flowchart of an edge word line management method of a memory device according to an exemplary embodiment of the inventive concept;

FIG. 27 is a block diagram illustrating a memory system according to an exemplary embodiment of the inventive concept being applied to a memory card system;

FIG. 28 is a block diagram illustrating a computing system including a memory system according to an exemplary embodiment of the inventive concept; and

FIG. 29 is a block diagram illustrating a memory system according to an exemplary embodiment of the inventive concept being applied to a solid state disk (SSD) system.

### DETAILED DESCRIPTION OF THE EMBODIMENTS

Hereinafter, exemplary embodiments of the inventive concept will be described in detail with reference to the accompanying drawings. The inventive concept may, however, be embodied in different forms and should not be construed as limited to the embodiments set forth herein. Like reference numerals may refer to like elements throughout. In the drawings, the dimensions and size of each structure may be exaggerated or reduced for clarity. All elements shown in the drawings may be composed of circuits. The terms of a singular form may include plural forms unless referred to the contrary.

FIG. 1 is a block diagram illustrating a memory system 100A according to an exemplary embodiment of the inventive concept.

As illustrated in FIG. 1, the memory system 100A may include a memory device 10A and a memory controller 20A. The memory device 10A may include a memory cell array 11 and a post-program manager 12-1A.

The memory cell array 11 may include a plurality of memory cells respectively disposed in a plurality of areas where a plurality of word lines intersect a plurality of bit lines. In an exemplary embodiment of the inventive concept, the plurality of memory cells may be flash memory cells. For example, the memory cell array 11 may be a NAND flash memory cell array or a NOR flash memory cell array. Hereinafter, a case where the plurality of memory cells are flash memory cells will be described.

The memory cell array 11 may have a string structure where a plurality of memory cells are serially connected to each other. For example, in each of a plurality of cell strings, a ground selection transistor, one or more dummy memory cells, a plurality of main memory cells, and a string selection transistor may be serially connected between a common source line CSL and a bit line BL. The one or more dummy memory cells may be disposed between the ground selection transistor and the plurality of main memory cells, thereby decreasing a coupling influence of the common source line CSL on the main memory cells. In other words, a dummy memory cell may be disposed in an edge of a main memory cell.

As another example, in each cell string, a ground selection transistor, one or more dummy memory cells, a plurality of main memory cells, one or more dummy memory cells, and a string selection transistor may be serially connected between a common source line CSL and a bit line BL.

Moreover, in each cell string, a plurality of memory cells may be programmed in order from a memory cell closest to a ground selection transistor connected to a global source line GSL to a memory cell farther away from the ground selection transistor, thereby minimizing back pattern dependency. Hereinafter, the global source line GSL may be referred to as a ground selection line.

For example, the memory cell array 11 may have two-dimensional (2D) planar NAND flash memory cell structure. As another example, the memory cell array 11 may have a three-dimensional (3D) vertical NAND (VNAND) flash memory cell.

In the present embodiment, the memory cell array 11 having a 3D structure may be monolithically formed in one or more physical levels of arrays of memory cells having an active area disposed on a silicon substrate and circuitry associated with an operation of each of the memory cells. The associated circuitry may be provided on or in the substrate. The term “monolithically” may denote that layers of each level of the memory cell array 11 are directly deposited on the layers of each underlying level of the memory cell array 11.

In an exemplary embodiment of the inventive concept, the memory cell array 11 having a 3D structure may include a plurality of NAND strings which are arranged in a vertical direction in an order such that at least one memory cell is disposed on another memory cell. The at least one memory cell may include a charge trap layer. U.S. Pat. Nos. 7,679,133, 8,553,466, 8,654,587 and 8,559,235 and U.S. Patent Application No. 2011/0233648 disclose elements of a 3D memory array which include a plurality of levels and in which word lines and/or bit lines are shared between the plurality of levels. The aforementioned patent documents are herein incorporated by reference in their entireties.

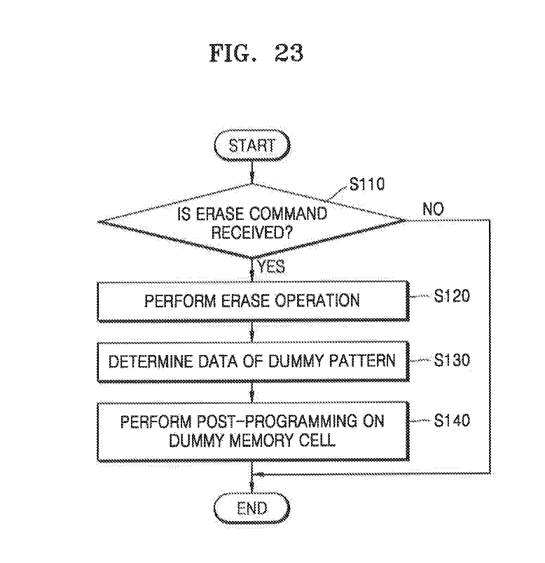

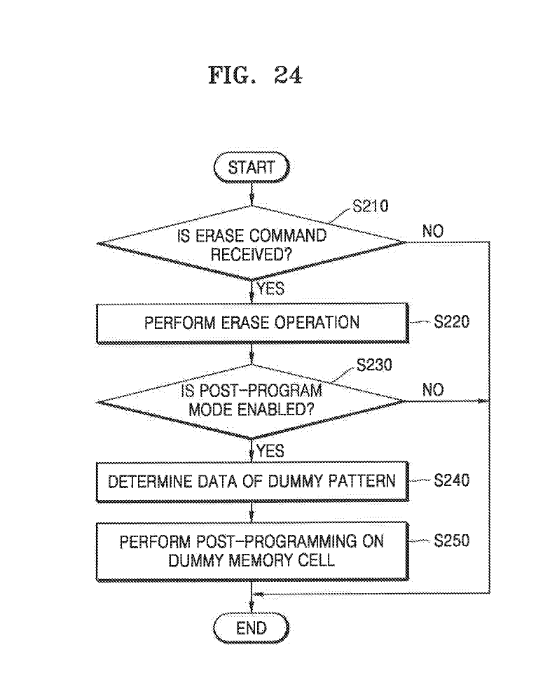

The post-program manager 12-1A may include hardware or software for performing an edge word line management method of the memory device 10A illustrated in FIG. 23 or 24.

The post-program manager 12-1A may terminate an erase operation based on an erase command received from the memory controller 20A, and then, may perform a post-program operation of writing data of a random dummy pattern in a dummy memory cell adjacent to a main memory cell of a memory block for which the erase operation has been performed. For example, the post-program manager 12-1A may perform an erase operation, and then, may perform a post-program operation of writing data of a dummy pattern in a dummy memory cell adjacent to a main memory cell of a cell string included in a memory block for which the erase operation has been performed.

For example, a dummy memory cell in which data of a dummy pattern is written through a post-program operation may be disposed between a main memory cell and a ground selection transistor of a cell string. For example, if a plurality of dummy memory cells are disposed between a main memory cell and a ground selection transistor of a cell string included in a memory block, the post-program manager 12-1A may perform an operation of writing data of a dummy pattern in a dummy memory cell most adjacent to the main memory cell.

The post-program manager 12-1A may randomly determine data of a dummy pattern used for post-programming. For example, when 0 is programmed in all dummy memory cells connected to a dummy word line, a main memory cell may be programmed N (where N is an integer equal to or more than one) times, and in this case, each of the dummy memory cells may be programmed 2N times. When this happens, each of the dummy memory cells may become a worst memory cell, thereby exerting a negative influence an adjacent main memory cell. However, when data of a dummy pattern is randomly determined, the negative influence of the dummy memory cells can be limited.

For example, the post-program manager 12-1A may determine, as data of a dummy pattern, data which is read through an initially set word line of a memory block to be erased before an erase operation and backed up. As another example, the post-program manager 12-1A may determine, as data of a dummy pattern, data read through an initially set word line of a memory block which is randomly determined before an erase operation. As another example, the post-program manager 12-1A may determine, as data of a dummy pattern, data obtained by inverting some of the data read through an initially set word line of a memory block which is randomly determined before an erase operation. As another example, the post-program manager 12-1A may determine, as data of a dummy pattern, one data pattern selected from two or more candidate data patterns by using information which is generated in a verification processing operation of an erase operation. As another example, the post-program manager 12-1A may set at least two candidate data patterns and may determine, as data of a dummy pattern, one data pattern selected from the at least two candidate data patterns, based on a phase which is detected at a certain time of one or more clock signals used in the memory device 10A.

As described above, the post-program manager 12-1A of the memory device 10A may generate data of a dummy pattern, and thus, data of a dummy pattern used for a post-program operation may not be supplied from the memory controller 20A.

When a post-program mode is enabled, the post-program manager 12-1A may perform a post-program operation. When the post-program mode is disabled, the post-program manager 12-1A may control a post-program operation of the memory device 10A so that the post-program operation is not performed. For example, if a program/erase cycle count for each memory block is greater than an initially set threshold value, the post-program manager 12-1A may set a corresponding memory block to a pre-program mode enable state.

The memory controller 20A may perform a control operation on the memory device 10A. For example, the memory controller 20A may generate an address ADDR, a command CMD, and a control signal CTRL for controlling the memory device 10A.

In addition, the memory controller 20A may supply the address ADDR, the command CMD, and the control signal CTRL to the memory device 10A to control a program (or write) operation, a read operation, and an erase operation on the memory device 10A. In addition, data DATA for the program operation and read data DATA may be transmitted or received between the memory controller 20A and the memory device 10A.

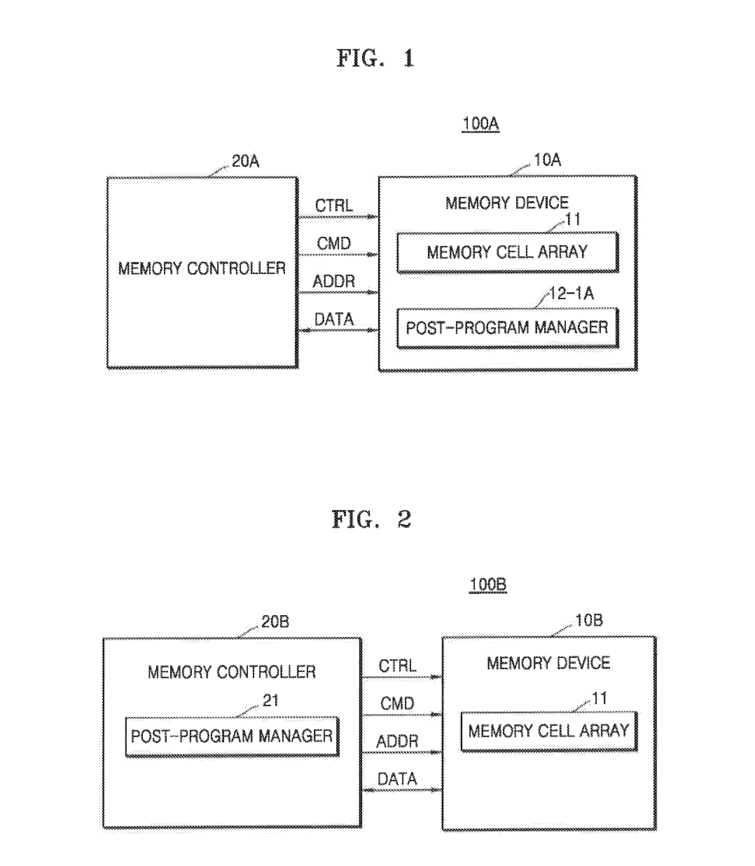

FIG. 2 is a block diagram illustrating a memory system 10B according to an exemplary embodiment of the inventive concept.

As illustrated in FIG. 2, the memory system 100B may include a memory device 10B and a memory controller 20B. The memory device 10B may include a memory cell array 11, and the memory controller 20B may include a post-program manager 21.

The memory cell array 11 of the memory device 10B has been described above with reference to FIG. 1, and thus, its repetitive description is not provided.

In the embodiment of FIG. 1, the post-program manager 12-1A is provided in the memory device 10A, but in the embodiment of FIG. 2, the post-program manager 21 is provided in the memory controller 20B.

The memory controller 20B may perform a control operation on the memory device 10B. For example, the memory controller 20B may generate an address ADDR, a command CMD, and a control signal CTRL for controlling the memory device 10B. In addition, the memory controller 20B may supply the address ADDR, the command CMD, and the control signal CTRL to the memory device 10B to control a program (or write) operation, a read operation, and an erase operation on the memory device 10B. In addition, data DATA for the program operation and read data DATA may be transmitted or received between the memory controller 20B and the memory device 10B.

The post-program manager 21 may include hardware or software for performing an edge word line management method of the memory device 10B illustrated in FIG. 23 or 24.

The post-program manager 21 may terminate an erase operation on the memory device 10B, and then, may transmit, to the memory device 10B, a program command, an address, and data of a random dummy pattern for performing a post-program operation of writing the data of the random dummy pattern in a dummy memory cell adjacent to a main memory cell of a memory block for which the erase operation has been performed.

For example, the post-program manager 21 may perform an erase operation, and select a dummy word line connected to a dummy memory cell adjacent to a main memory cell of a cell string included in a memory block for which the erase operation has been performed. The post-program manager 21 may transmit, to the memory device 10B, a program command, an address, and data for programming data of a random dummy pattern in dummy memory cells connected to the selected dummy word line.

For example, the post-program manager 21 may select a dummy word line connected to a dummy memory cell disposed between a ground selection transistor and a main memory cell of a cell string. The post-program manager 21 may transmit, to the memory device 10B, a program command, an address, and data for programming data of a random dummy pattern in dummy memory cells connected to the selected dummy word line.

For example, if a plurality of dummy memory cells are disposed between a ground selection transistor and a main memory cell of a cell string, the post-program manager 21 may select a dummy word line connected to a dummy memory cell most adjacent to the main memory cell. The post-program manager 21 may transmit, to the memory device 10B, a program command, an address, and data for programming data of a random dummy pattern in dummy memory cells connected to the selected dummy word line.

The post-program manager 21 may randomly determine data of a dummy pattern used for post-programming and may transmit the randomly determined data of the dummy pattern to the memory device 10B. For example, the post-program manager 21 may determine, as data of a dummy pattern, data which is read through an initially set word line of a memory block to be erased before an erase operation. As another example, the post-program manager 21 may determine, as data of a dummy pattern, data read through an initially set word line of a memory block which is randomly determined before an erase operation. As another example, the post-program manager 21 may determine, as data of a dummy pattern, data obtained by inverting some of the data read through an initially set word line of a memory block which is randomly determined before an erase operation. As another example, the post-program manager 21 may determine, as data of a dummy pattern, one data pattern selected from two or more candidate data patterns by using information which is generated in a verification processing operation of an erase operation. As another example, the post-program manager 21 may set at least two candidate data patterns and may determine, as data of a dummy pattern, one data pattern selected from the at least two candidate data patterns, based on a phase which is detected at a certain time of one or more clock signals used in the memory device 10B.

When the post-program mode is enabled, the post-program manager 21 may perform a post-program operation. When the post-program mode is disabled, the post-program manager 21 may control a post-program operation of the memory device 10B so that the post-program operation is not performed. For example, if a program/erase cycle count for each memory block is greater than an initially set threshold value, the post-program manager 21 may set a corresponding memory block to a post-program mode enable state.

FIG. 3 is a block schematically illustrating a memory system 100C according to an exemplary embodiment of the inventive concept.

As illustrated in FIG. 3, the memory system 100C may include a memory device 10C and a memory controller 20C. The memory device 10C may include a memory cell array 11 and a pre-program manager 12-1C.

The memory cell array 11 of the memory device 10C has been described above with reference to FIG. 1, and thus, its repetitive description is not provided. In addition, the memory controller 20C may perform substantially the same operation as that of the memory controller 20A of FIG. 1, and thus, its repetitive description is not provided.

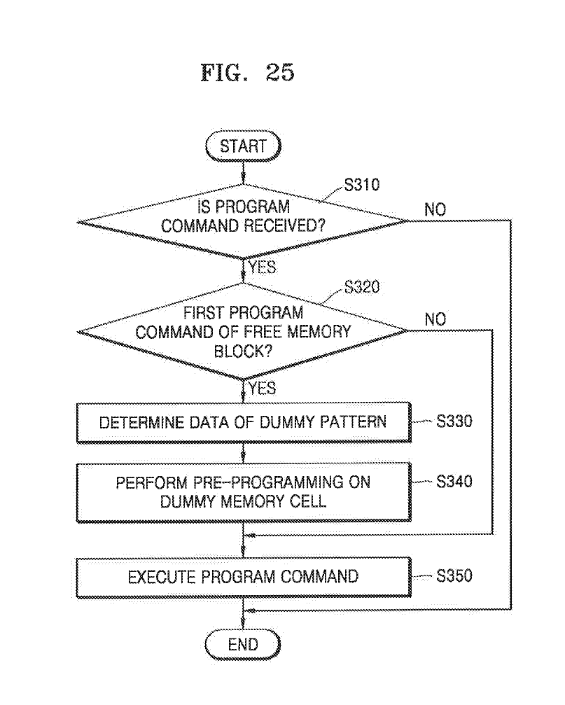

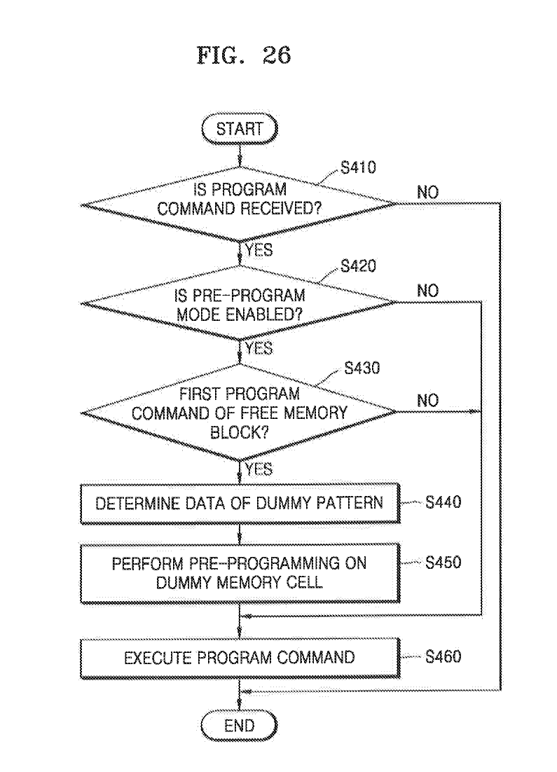

The pre-program manager 12-1C may include hardware or software for performing an edge word line management method of the memory device 10C illustrated in FIG. 25 or 26.

When a program command for performing a first program operation on a free memory block of the memory device 10C is received from the memory controller 20C, the pre-program manager 12-1C may control the memory device 10C to perform a pre-program operation of writing data of a random dummy pattern in a dummy memory cell adjacent to a main memory cell of a cell string included in the free memory block, and then, execute the program command. Here, the free memory block denotes an empty memory block which has not yet been written after an erase operation is performed.

In other words, the pre-program manager 12-1C may perform a pre-program operation of writing data of a random dummy pattern in a dummy memory cell adjacent to a main memory cell of a cell string included in a free memory block before a first program operation is performed for the free memory block.

For example, a dummy memory cell in which data of a dummy pattern is written through a pre-program operation may be disposed between a ground selection transistor and a main memory cell. For example, if a plurality of dummy memory cells are disposed between a ground selection transistor and a main memory cell of a cell string included in a memory block, the pre-program manager 12-1C may perform an operation of writing data of a dummy pattern in a dummy memory cell most adjacent to the main memory cell.

The pre-program manager 12-1C may randomly determine data of a dummy pattern used for pre-programming. For example, the pre-program manager 12-1C may set at least two candidate data patterns and may determine, as data of a dummy pattern, one data pattern selected from the at least two candidate data patterns, based on a phase which is detected at a certain time of one or more clock signals used in the memory device 10C.

As described above, the pre-program manager 12-1C of the memory device 10C may generate data of a dummy pattern, and thus, data of a dummy pattern used for a pre-program operation may not be supplied from the memory controller 20C.

When a pre-program mode is enabled, the pre-program manager 12-1C may perform a pre-program operation. When the pre-program mode is disabled, the pre-program manager 12-1C may control a pre-program operation of the memory device 10C so that the pre-program operation is not performed. For example, if a program/erase cycle count for each memory block is greater than an initially set threshold value, the pre-program manager 12-1C may set a corresponding memory block to a pre-program mode enable state.

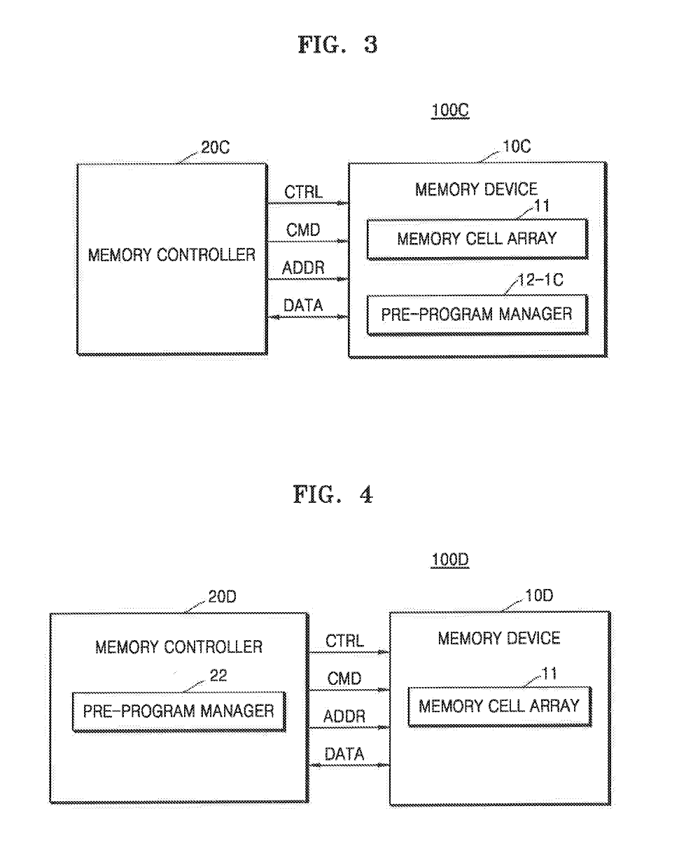

FIG. 4 is a block diagram illustrating a memory system 100D according to an exemplary embodiment of the inventive concept.

As illustrated in FIG. 4, the memory system 100D may include a memory device 10D and a memory controller 20D. The memory device 10D may include a memory cell array 11, and the memory controller 20D may include a pre-program manager 22.

The memory cell array 11 of the memory device 10D has been described above with reference to FIG. 1, and thus, its repetitive description is not provided.

In the embodiment of FIG. 3, the pre-program manager 12-1C is provided in the memory device 10C, but in the embodiment of FIG. 4, the pre-program manager 22 is provided in the memory controller 20D.

The memory controller 20D may perform a control operation on the memory device 10D. For example, the memory controller 20D may generate an address ADDR, a command CMD, and a control signal CTRL for controlling the memory device 10D. In addition, the memory controller 20D may supply the address ADDR, the command CMD, and the control signal CTRL to the memory device 10D to control a program (or write) operation, a read operation, and an erase operation on the memory device 10D.

In addition, data DATA for the program operation and read data DATA may be transmitted or received between the memory controller 20D and the memory device 10D.

The pre-program manager 22 may include hardware or software for performing an edge word line management method of the memory device 10D illustrated in FIG. 25 or 26.

The pre-program manager 22 may transmit, to the memory device 10D, a program command, an address, and data of a random dummy pattern for performing a pre-program operation of writing the data of the random dummy pattern in a dummy memory cell adjacent to a main memory cell of a cell string included in a free memory block before a first pre-program operation is performed for the free memory block.

For example, the pre-program manager 22 may select a dummy word line connected to a dummy memory cell disposed between a ground selection transistor and a main memory cell of a cell string. The pre-program manager 22 may transmit, to the memory device 10D, a program command, an address, and data for programming data of a random dummy pattern in dummy memory cells connected to the selected dummy word line.

For example, if a plurality of dummy memory cells are disposed between a ground selection transistor and a main memory cell of a cell string, the pre-program manager 22 may select a dummy word line connected to a dummy memory cell most adjacent to the main memory cell. The pre-program manager 22 may transmit, to the memory device 10D, a program command, an address, and data for programming data of a random dummy pattern in dummy memory cells connected to the selected dummy word line.

The pre-program manager 22 may randomly determine data of a dummy pattern used for pre-programming. For example, the pre-program manager 22 may set at least two candidate data patterns and may determine, as data of a dummy pattern, one data pattern selected from the at least two candidate data patterns, based on a phase which is detected at a certain time of one or more clock signals used in the memory device 10D.

When the pre-program mode is enabled, the pre-program manager 22 may perform a pre-program operation. When the pre-program mode is disabled, the pre-program manager 22 may control a pre-program operation of the memory device 10D so that the pre-program operation is not performed. For example, if a program/erase cycle count for each memory block is greater than an initially set threshold value, the pre-program manager 22 may set a corresponding memory block to a pre-program mode enable state.

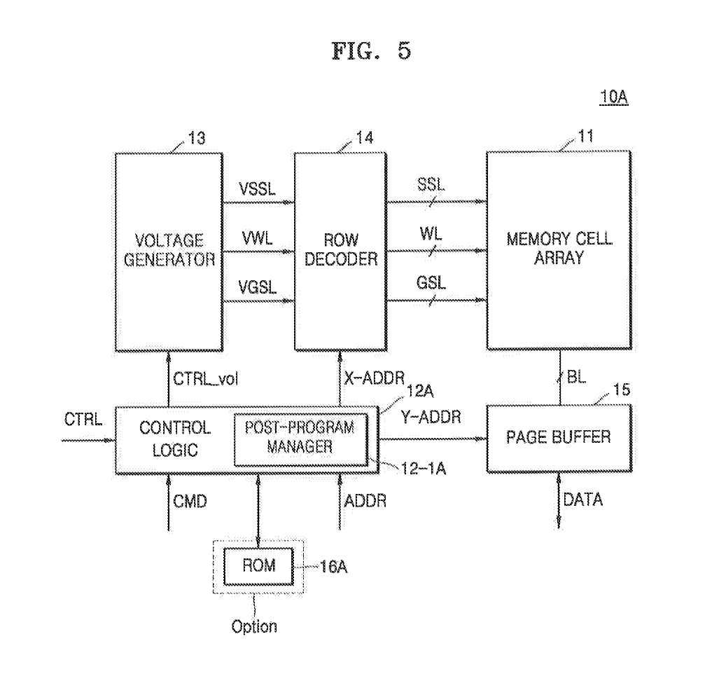

FIG. 5 is a block diagram illustrating the memory device 10A included in the memory system 100A of FIG. 1 according to an exemplary embodiment of the inventive concept.

Referring to FIG. 5, the memory device 10A may include a memory cell array 11, a control logic 12A, a voltage generator 13, a row decoder 14, and a page buffer 15. The memory device 10A may optionally use a read-only memory (ROM) 16A. For example, pieces of candidate data which are to be used as a dummy pattern may be stored in the ROM 16A in a manufacturing process. As another example, data of a dummy pattern may be determined by using data, which is read from the memory cell array 11 and stored in the page buffer 15, without using the ROM 16A. As another example, a data pattern which is generated as different logic values in an even/odd bit line may be determined as data of a dummy pattern by using a connection structure of a bit line and the page buffer 15. Hereinafter, the elements included in the memory device 10A will be described in detail.

The memory cell array 11 may be connected to one or more string selection lines SSL, a plurality of word lines WL, and one or more ground selection lines GSL and may also be connected to a plurality of bit lines BL. The memory cell array 11 may include a plurality of memory cells respectively disposed in a plurality of areas where the plurality of word lines WL intersect the plurality of bit lines BL. The plurality of word lines WL may include a plurality of main word lines MWL and one or more dummy word lines DWL. The one or more dummy word lines DWL can enhance the data reliability of a main word line MWL.

When an erase voltage is applied to the memory cell array 11, a plurality of memory cells MC may be in an erase state. When a program voltage is applied to the memory cell array 11, the plurality of memory cells MC may be in a program state. In this case, each of the memory cells MC may have one of the erase state and first to nth program states P1 to Pn which are classified based on a threshold voltage.

Here, n may be a natural number equal to or more than two. For example, if each of the memory cells MC is a two-bit level cell, n may be three. As another example, if each of the memory cells MC is a three-bit level cell, n may be seven. As another example, if each of the memory cells MC is a four-bit level cell, n may be fifteen. As described above, the plurality of memory cells MC may include multi-level cells.

However, the inventive concept is not limited thereto. In an exemplary embodiment of the inventive concept, the plurality of memory cells MC may include single level cells.

The control logic 12A may output various control signals for writing data in the memory cell array 11, reading the data from the memory cell array 11, or erasing the memory cell array 11, based on a command CMD, an address ADDR, and a control signal CTRL received from the memory controller 20A. Therefore, the control logic 12A may control various operations of the memory device 10A.

The control logic 12A may include a post-program manager 12-1A. The post-program manager 12-1A may terminate an erase operation based on an erase command, and then, may output various control signals for performing a post-program operation of writing data of a random dummy pattern in a dummy memory cell adjacent to a main memory cell of a memory block for which the erase operation has been performed.

The various control signals output from the control logic 12A may be supplied to the voltage generator 13, the row decoder 14, and the page buffer 15. For example, the control logic 12A may be supply a voltage control signal CTRL_vol to the voltage generator 13, supply a row address X_ADDR to the row decoder 14, and supply a column address Y_ADDR to the page buffer 15.

The voltage generator 13 may generate various kinds of voltages for performing a program operation, a read operation, and an erase operation on the memory cell array 11, based on the voltage control signal CTRL_vol. For example, the voltage generator 13 may generate a first driving voltage VWL for driving the plurality of word lines WL, a second driving voltage VSSL for driving the plurality of string selection lines SSL, and a third driving voltage VGSL for driving the plurality of ground selection lines GSL.

In this case, the first driving voltage VWL may be a program voltage (or a write voltage), a read voltage, an erase voltage, a pass voltage, or a program verification voltage. In addition, the second driving voltage VSSL may be a string selection voltage, for example, an on voltage or an off voltage. Furthermore, the third driving voltage VGSL may be a ground selection voltage, for example, an on voltage or an off voltage.

The row decoder 14 may be connected to the memory cell array 11 through the plurality of word lines WL and may activate some of the plurality of word lines WL in response to the row address X_ADDR received from the control logic 12A. For example, in the read operation, the row decoder 14 may apply the read voltage to a selected word line and may apply the pass voltage to an unselected word line.

In the program operation, the row decoder 14 may apply the program voltage to a selected word line and may apply the pass voltage to an unselected word line.

Moreover, in the erase operation, the row decoder 14 may apply the erase voltage (for example, 0 V) to the word lines WL and may float the string selection line SSL and the ground selection line GSL.

The page buffer 15 may be connected to the memory cell array 11 through the plurality of bit lines BL. For example, in the read operation, the page buffer 15 may operate as a sense amplifier to output data DATA stored in the memory cell array 11. In addition, in the program operation, the page buffer 15 may operate as a write driver to input data DATA, which is to be stored in the memory cell array 11, to the memory cell array 11.

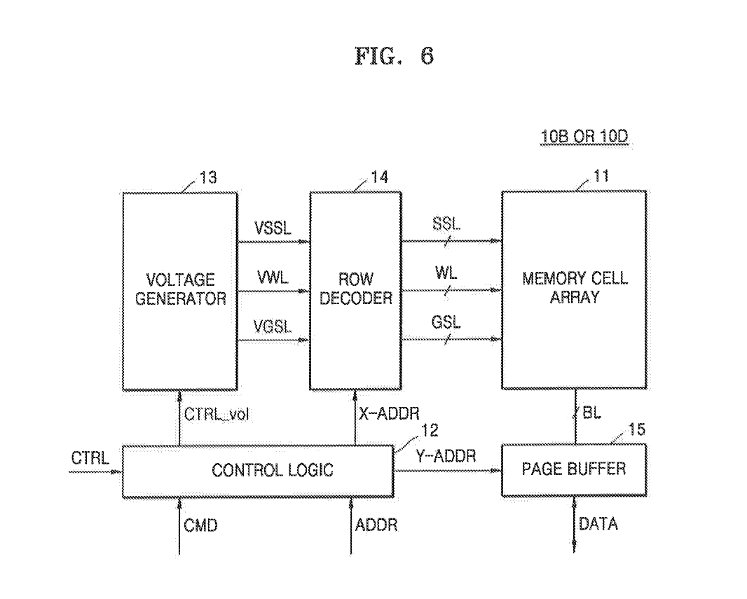

FIG. 6 is a block diagram illustrating the memory device 10B or 10D included in the memory system 100B or 100D of FIG. 2 or 4 according to an exemplary embodiment of the inventive concept.

Referring to FIG. 6, the memory device 10B or 10D may include a memory cell array 11, a control logic 12, a voltage generator 13, a row decoder 14, and a page buffer 15. The memory cell array 11, the voltage generator 13, the row decoder 14, and the page buffer 15 have been described above with reference to FIG. 6, and thus, their repetitive descriptions are not provided.

Moreover, the control logic 12 may have a configuration where the post-program manager 12-1A of the control logic 12A illustrated in FIG. 5 is omitted. The control logic 12 may output various control signals for writing data in the memory cell array 11, reading the data from the memory cell array 11, or erasing the memory cell array 11, based on a command CMD, an address ADDR, and a control signal CTRL received from the memory controller 20B (or 20D). Therefore, the control logic 12 may control various operations of the memory device 10B or 10D.

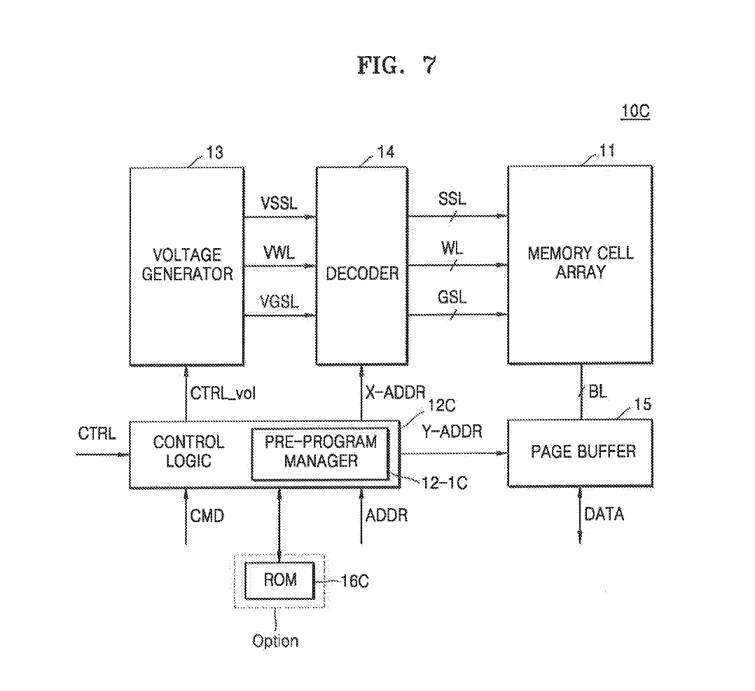

FIG. 7 is a block diagram illustrating the memory device 10C included in the memory system 100C of FIG. 3 according to an exemplary embodiment of the inventive concept.

Referring to FIG. 7, the memory device 10C may include a memory cell array 11, a control logic 12C, a voltage generator 13, a row decoder 14, and a page buffer 15. The memory device 10C may optionally use a ROM 16C. For example, pieces of candidate data which are to be used as a dummy pattern may be stored in the ROM 16C in a manufacturing process. As another example, data of a dummy pattern may be determined by using data, which is read from the memory cell array 11 and stored in the page buffer 15, without using the ROM 16C. As another example, a data pattern which is generated as different logic values in an even/odd bit line may be determined as data of a dummy pattern by using a connection structure of a bit line and the page buffer 15. The memory cell array 11, the voltage generator 13, the row decoder 14, and the page buffer 15 have been described above with reference to FIG. 5, and thus, their repetitive descriptions are not provided.

The control logic 12C may output various control signals for writing data in the memory cell array 11, reading the data from the memory cell array 11, or erasing the memory cell array 11, based on a command CMD, an address ADDR, and a control signal CTRL received from the memory controller 20C. Therefore, the control logic 12C may control various operations of the memory device 10C.

The control logic 12C may include a pre-program manager 12-1C. The pre-program manager 12-1C may terminate an erase operation based on an erase command, and then, may output various control signals for performing a post-program operation of writing data of a random dummy pattern in a dummy memory cell adjacent to a main memory cell of a memory block for which the erase operation has been performed.

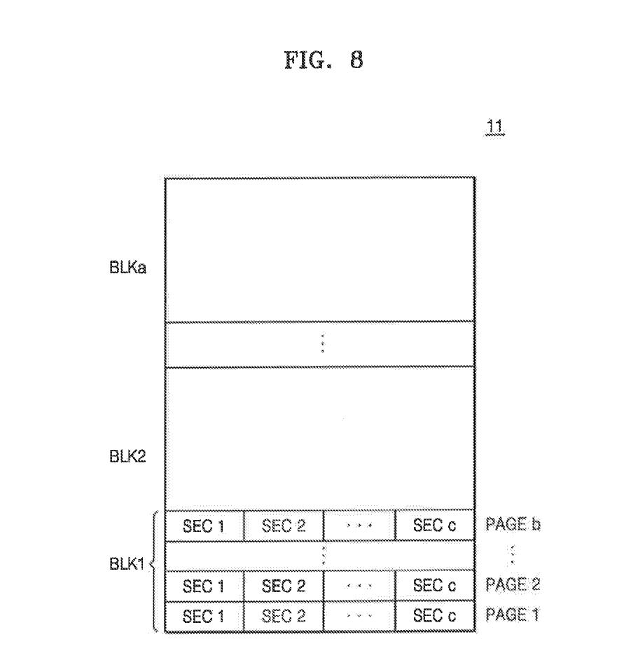

FIG. 8 illustrates the memory cell array 11 illustrated in FIGS. 5 to 7 according to an exemplary embodiment of the inventive concept.

Referring to FIG. 8, the memory cell array 11 may be a flash memory cell array. In this case, the memory cell array 11 may include a (where a is an integer equal to or more than two) number of memory blocks BLK1 to BLKa. Each of the memory blocks BLK1 to BLKa may include b (where b is an integer equal to or more than two) number of pages PAGE1 to PAGEb. Each of the pages PAGE1 to PAGEb may include c (where c is an integer equal to or more than two) number of sectors SEC1 to SECc. In FIG. 8, for convenience of illustration, only the memory block BLK1 is illustrated as including the pages PAGE1 to PAGEb and the sectors SEC1 to SECc. However, the other memory blocks BLK2 to BLKa may each have the same structure as that of the memory block BLK1.

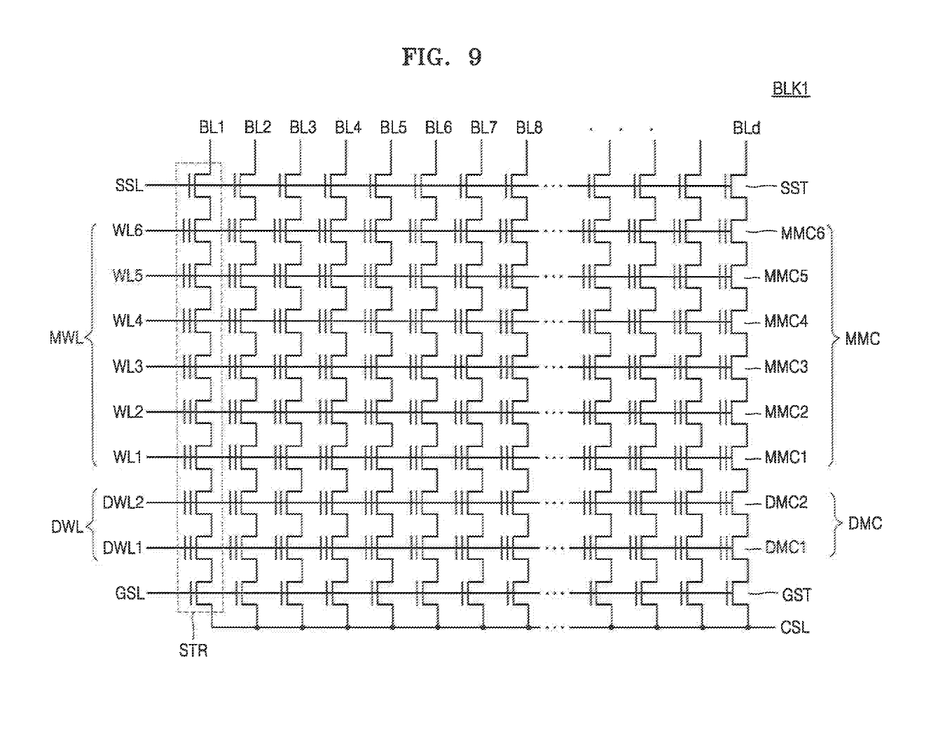

FIG. 9 is a circuit diagram illustrating the memory block BLK1 included in the memory cell array illustrated in FIG. 8 according to an exemplary embodiment of the inventive concept.

Referring to FIG. 9, a first memory block BLK1 may be a NAND flash memory having a vertical structure, and each of the memory blocks BLK1 to BLKa illustrated in FIG. 8 may be implemented as shown in FIG. 9. The first memory block BLK1 may include, for example, d (where d is an integer equal to or more than two) number of cell strings STR where eight memory cells are serially connected to each other. Each of the string cells STR may include a string selection transistor SST and a ground selection transistor GST which are respectively connected to both ends of memory cells serially connected to each other. Here, one or more memory cells adjacent to the ground selection transistor GST among eight memory cells included in one cell string may each be set as a dummy memory cell. The ground selection transistor GST may be connected to a ground selection line GSL and the string selection transistor SST may be connected to a string selection line SSL.

In the embodiment of FIG. 9, two memory cells adjacent to the ground selection transistor GST may each be set as a dummy memory cell. Therefore, six of eight memory cells included in one cell string may be set as a main memory cell MMC. As another example, one or more dummy memory cells DMC may be added between the string selection transistor SST and the main memory cell MMC.

Moreover, a dummy word line DWL may be connected to the dummy memory cells DMC, and a main word line MWL may be connected to the main memory cell MMC. As described above, the dummy memory cell DMC1 and DMC2 may be disposed between the ground selection transistor GST and a plurality of main memory cells MMC1 to MMC6, thereby decreasing a coupling influence of the common source line CSL on the main memory cells MMC. In other words, one or more dummy memory cells DMC may be disposed in an edge of the main memory cell MMC.

Here, the number of cell strings STR, the number of dummy word lines DWL (e.g., DWL1 and DWL2), the number of main word lines MWL (e.g., WL1 to WL6), and the number of bit lines BL (e.g., BL1 to BLd) may be variously changed according to exemplary embodiments of the inventive concept.

A NAND flash memory device having a structure illustrated in FIG. 9 may be erased in units of one memory block and may be programmed by a page unit corresponding to each word line. For example, if a memory cell is a single level cell, one page may correspond to each word line. As another example, if the memory cell is a multi-level cell or a triple-level cell, a plurality of pages may correspond to each word line.

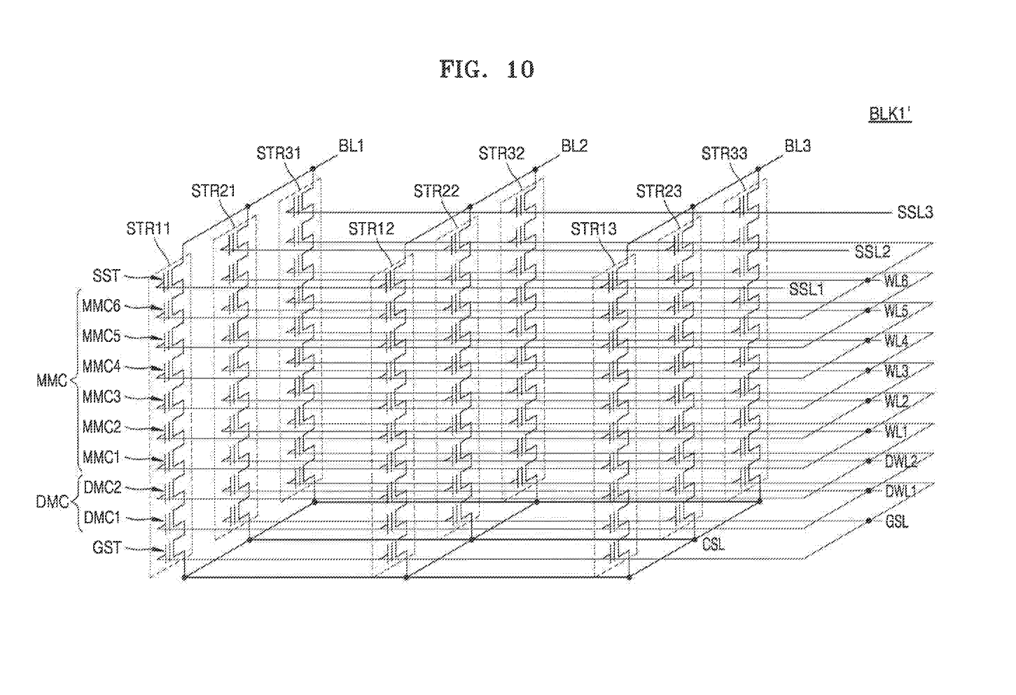

FIG. 10 is a circuit diagram illustrating a memory block included in the memory cell array illustrated in FIG. 8 according to an exemplary embodiment of the inventive concept.

FIG. 10 is a circuit diagram illustrating another example BLK1′ of a memory block included in the memory cell array illustrated in FIG. 8.

Referring to FIG. 10, a first memory block BLK1′ may be a NAND flash memory having a vertical structure, and each of the memory blocks BLK1 to BLKa illustrated in FIG. 8 may be implemented as shown in FIG. 10. The first memory block BLK1′ may include, for example, a plurality of cell strings STR11 to STR33, a plurality of word lines DWL1, DWL2 and WL1 to WL6, a plurality of bit lines BL1 to BL3, a ground selection line GSL, a plurality of string selection lines SSL1 to SSL3, and a common source line CSL. Here, the number of cell strings, the number of word lines, the number of bit lines, the number of ground selection lines, and the number of string selection lines may be variously changed according to exemplary embodiments of the inventive concept.

The cell strings STR11 to STR33 may be connected between the bit lines BL1 to BL3 and the common source line CSL. Each cell string (for example, STR11) may include a string selection transistor SST, a plurality of memory cells DMC (e.g., DMC1 and DMC2) and MMC (e.g., MMC1 to MMC6), and a ground selection transistor GST which are serially connected to each other.

In the embodiment of FIG. 10, two memory cells adjacent to the ground selection transistor GST in each cell string may each be set as a dummy memory cell DMC. Therefore, six of eight memory cells included in one cell string may each be set as a main memory cell MMC. As another example, one or more dummy memory cells DMC may be added between the string selection transistor SST and the main memory cell MMC.

The string selection transistor SST may be connected to the string selection lines SSL1 to SSL3. A plurality of memory cells MMC and DMC may be respectively connected to a plurality of word lines WL and DWL corresponding thereto. The ground selection transistor GST may be connected to the ground selection line GSL. The string selection transistor SST may be connected to a bit line corresponding thereto, and the ground selection transistor GST may be connected to the common source line CSL.

Word lines (for example, WL1) of the same height may be connected in common, and the string selection lines SSL1 to SSL3 may be spaced apart from each other. When a plurality of memory cells which are connected to the word line WL1 and are included in a plurality of cell strings NS 11 to NS 13 are programmed, the word line WL1 and the string selection line SSL1 may be selected.

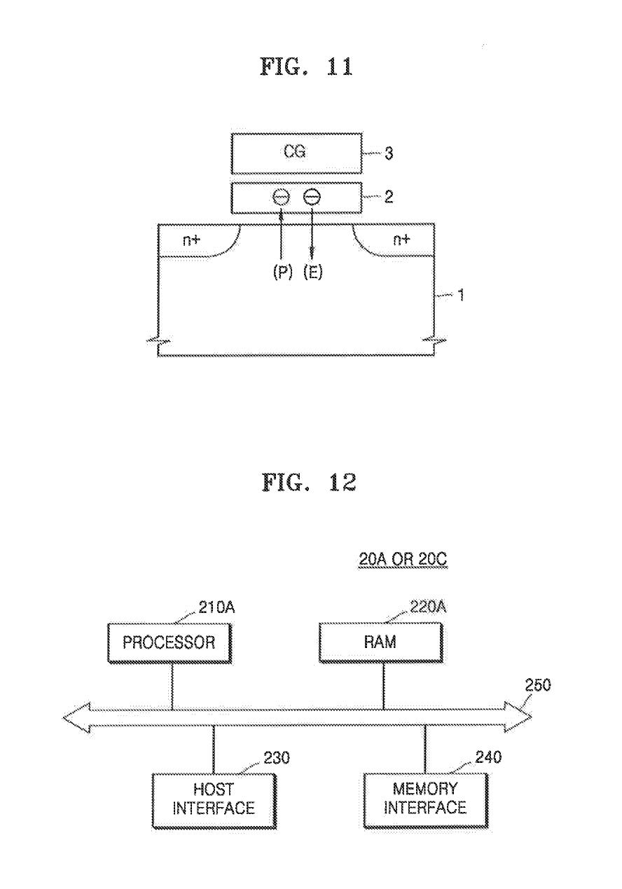

FIG. 11 is a cross-sectional view illustrating a memory cell included in the memory block illustrated in FIG. 9 or 10. Here, the memory cell may be a dummy memory cell DMC or a main memory cell MMC.

Referring to FIG. 11, the memory cell may include a channel area 1, a charge storage layer 2, and a control gate (CG) 3. For example, the charge storage layer 2 may be implemented with a floating gate which is a conductor, and a memory cell having such a structure may be referred to as a floating gate structure cell. As another example, the charge storage layer 2 may be implemented with a nonconductor (for example, SiN), and a memory cell having such a structure may be referred to as a charge trap flash (CTF) cell.

To perform a program operation on a memory cell, a relatively high program voltage may be applied to the control gate 3, and a relatively low voltage (for example, 0 V) may be applied to the channel area 1. Based on such a bias condition, an electric field may be generated in a direction from the control gate 3 to the channel area 1. Therefore, electric charges (for example, electrons) may move in an arrow P direction (a direction from the channel area 1 to the charge storage layer 2), and thus, the memory cell may be programmed.

Moreover, to perform an erase operation on the memory cell, a relatively low voltage (for example, 0 V) may be applied to the control gate 3, and a relatively high program voltage may be applied to the channel area 1. Based on such a bias condition, an electric field may be generated in a direction from the channel area 1 to the control gate 3. Therefore, electric charges (for example, electrons) may move in an arrow E direction (a direction from the charge storage layer 2 to the channel area 1), and thus, the memory cell may be programmed.

FIG. 12 illustrates a block configuration of a memory controller 20A or 20C illustrated in FIG. 1 or 3 according to an exemplary embodiment of the inventive concept.

As illustrated in FIG. 12, the memory controller 20A or 20C may include a processor 210A, a random access memory (RAM) 220A, a host interface 230, a memory interface 240, and a bus 250.

The elements of the memory controller 20 may be electrically connected to each other through the bus 250.

The processor 210A may control an operation of the memory system 100A or 100C by using a program code and data which are stored in the RAM 220A. For example, the processor 210A may be implemented with a microprocessor or a central processing unit (CPU). In initializing the memory system 100A or 100C, the processor 210A may read a program code and data, which are used for controlling operations performed by the memory system 100A or 100C, from the memory device 10A or 10C and may load the program code and the data into the RAM 220A.

The processor 210A may supply a read command and an address to the memory device 10A or 10C in a read operation, supply a program command, an address, and data to the memory device 10A or 10C in a program operation, and supply an erase command and an address to the memory device 10A or 10C in an erase operation. In addition, the processor 210A may convert a logical address, received from a host, into a physical address by using system data stored in the RAM 220A.

The host interface 230 may include a data exchange protocol for exchanging data with the host connected to the memory system 100A or 100C and may connect the memory system 100A or 100C to the host. The host interface 230 may be implemented with an advanced technology attachment (ATA) interface, a serial-ATA (SATA) interface, a parallel-ATA (PATA) interface, a universal serial bus (USB), a serial attached small computer system (SAS) interface, a small computer system interface (SCSI), an embedded multi-media card (eMMC) interface, or a universal flash storage (UFS) interface. However, the present embodiment is not limited thereto. The host interface 230 may receive a command, an address, and data from the host or may transmit data to the host according to control by the processor 210A.

The memory interface 240 may be electrically connected to the memory device 10A or 10C. The memory interface 240 may transmit a command, an address, and data to the memory device 10A or 10C or may receive data from the memory device 10A or 10C according to control by the processor 210A. The memory interface 240 may be configured to support an NAND flash memory or a NOR flash memory. The memory interface 240 may be configured to perform software or hardware interleaving operations through a plurality of channels.

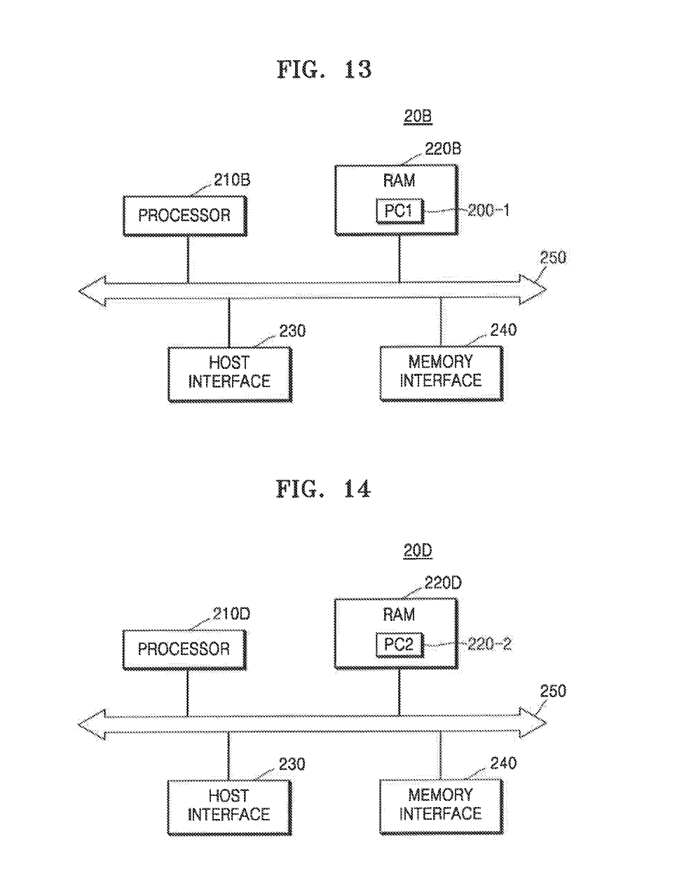

FIG. 13 illustrates a block configuration of the memory controller 20B illustrated in FIG. 2 according to an exemplary embodiment of the inventive concept.

As illustrated in FIG. 13, the memory controller 20B may include a processor 210B, a RAM 220B, a host interface 230, a memory interface 240, and a bus 250.

A program code and data, which are used for controlling operations performed by the memory system 100B, may be stored in the RAM 220B. For example, in initializing the memory system 100B, the processor 210B may read the program code and the data, which are used for controlling the operations performed by the memory system 100B, from the memory device 10B and may load the program code and the data into the RAM 220B. Particularly, the RAM 220B may store a program code (PC1) 220-1 for performing a post-program management operation.

The processor 210B may control an operation of the memory system 100B by using the program code and the data which are stored in the RAM 220B. For example, the processor 210B may perform the operation of the post-program manager 21 of FIG. 2 by using the program code (PC1) 220-1 stored in the RAM 220B. For example, the processor 210B may perform the edge word line management method of the memory device illustrated in FIG. 23 or 24 by using the program code (PC1) 220-1 stored in the RAM 220B.

The host interface 230, the memory interface 240, and the bus 250 have been described above with reference to FIG. 12, and thus, their repetitive descriptions are not provided.

FIG. 14 illustrates a block configuration of a memory controller 20D illustrated in FIG. 4 according to an exemplary embodiment of the inventive concept.

As illustrated in FIG. 14, the memory controller 20D may include a processor 210D, a RAM 220D, a host interface 230, a memory interface 240, and a bus 250.

A program code and data, which are used for controlling operations performed by the memory system 100D, may be stored in the RAM 220D. For example, in initializing the memory system 100D, the processor 210D may read the program code and the data, which are used for controlling the operations performed by the memory system 100D, from the memory device 10D and may load the program code and the data into the RAM 220D. Particularly, the RAM 220D may store a program code (PC2) 220-2 for performing a pre-program management operation.

The processor 210D may control an operation of the memory system 100D by using the program code and the data which are stored in the RAM 220D. For example, the processor 210D may perform the operation of the pre-program manager 22 of FIG. 4 by using the program code (PC2) 220-2 stored in the RAM 220D. For example, the processor 210D may perform the edge word line management method of the memory device illustrated in FIG. 25 or 26 by using the program code (PC2) 220-2 stored in the RAM 220D.

The host interface 230, the memory interface 240, and the bus 250 have been described above with reference to FIG. 12, and thus, their repetitive descriptions are not provided.

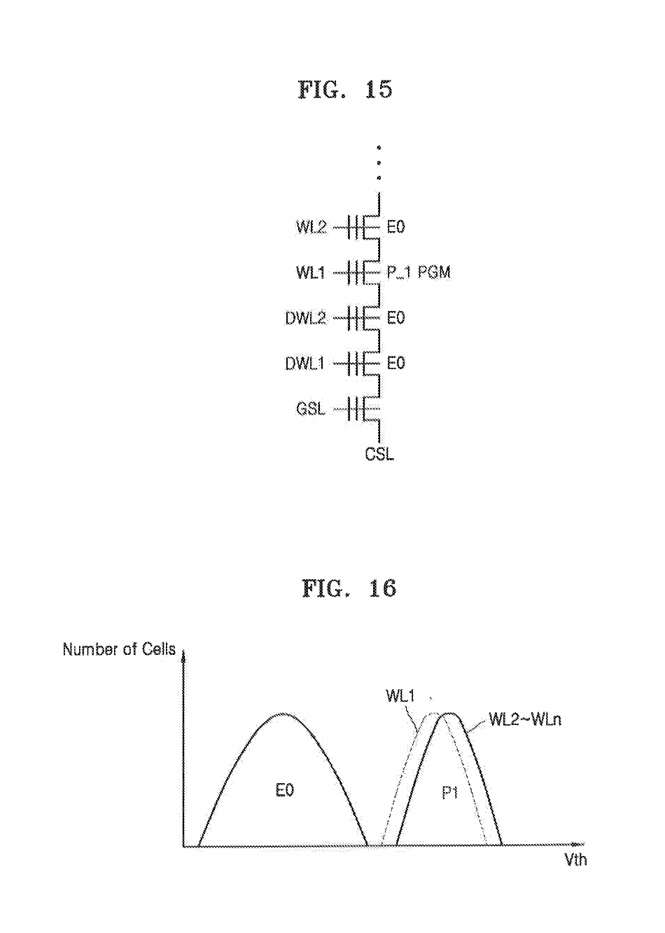

FIG. 15 shows an initial program state in one cell string included in the memory block illustrated in FIG. 9 or 10 under a condition where the post-program mode or the preprogram mode is disabled according to an exemplary embodiment of the inventive concept.

Referring to FIG. 15, a cell string may have a string structure where a plurality of memory cells are serially connected to each other. For example, two dummy memory cells DMC1 and DMC2 may be disposed between a ground selection transistor and a main memory cell MMC1, thereby decreasing an influence of a common source line CSL on a main memory cell MMC. In addition, a plurality of memory cells may be programmed in order from a memory cell closest to a ground selection line GSL to a memory cell farther away from the ground selection line GSL. In FIG. 15, the dummy memory cells DMC1 and DMC2 may be respectively connected to dummy word lines DWL1 and DWL2.

Therefore, an erase operation may be performed under a condition where the post-program mode or the pre-program mode is disabled, and then, an initial program operation may be performed for the main memory cell MMC1 closest to the ground selection line GSL. In other words, the main memory cell MMC1 which is first connected to the word line WL1 after the erase operation may be programmed (P_1 PGM).

According to an exemplary embodiment of the inventive concept, a threshold voltage variation of word line-based memory cells based on program execution under a condition where the post-program mode or the preprogram mode is disabled is shown in FIG. 16.

Referring to FIG. 16, it may be seen that a threshold voltage variation of a program state P1 of memory cells connected to a main word line WL1 is shifted toward a threshold voltage of an erase state E0 in comparison with a threshold voltage variation of a program state P1 of memory cells connected to main word lines WL2 to WLn (where n is an integer equal to or more than three). Since the main word line WL1 is programmed in a state where adjacent pages are all erased, most of the trapped charges may be used for first programming a page of the main word line WL1 after the erase operation. For this reason, as shown in FIG. 16, the reliability of the memory cells connected to the main word line WL1 is the lowest in the cell string.

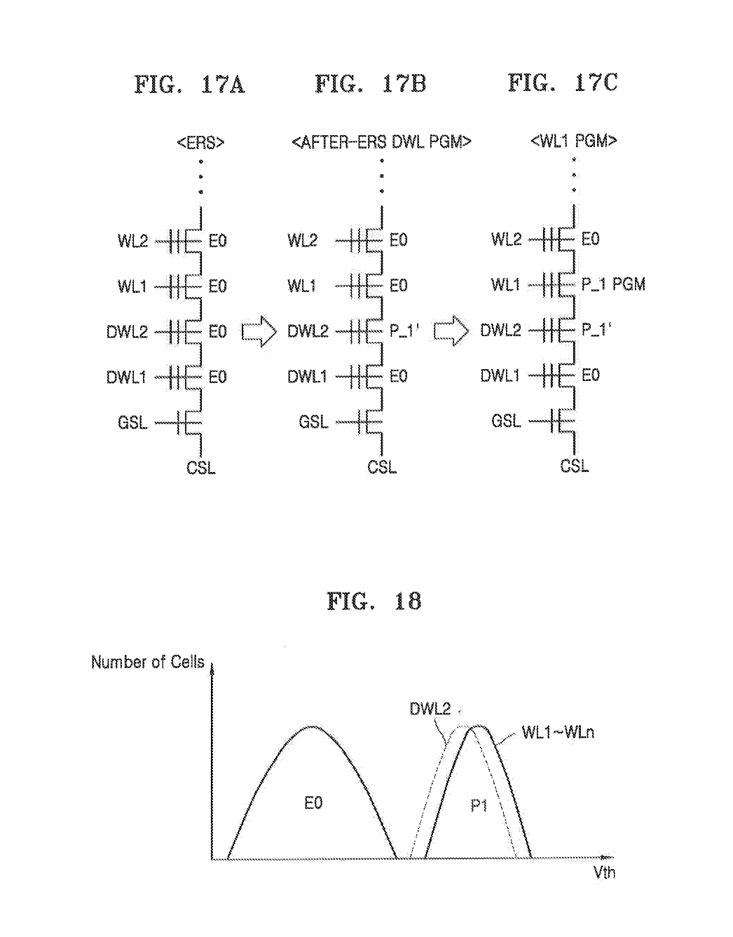

FIG. 17 shows an after-erase-operation program process for one cell string included in the memory block illustrated in FIG. 9 or 10 under a condition where the post-program mode or the preprogram mode is disabled according to an exemplary embodiment of the inventive concept.

FIG. 17A shows a state of each of a dummy memory cell DMC and a main memory cell MMC included in a cell string included in a memory block for which an erase operation has been performed. In other words, main memory cells MMC1 to MMCn of main word lines WL1 to WLn and dummy memory cells DMC1 and DMC2 which are connected to dummy word lines DWL1 and DWL2 after the erase operation is performed may all have a threshold voltage of an erase state E0.

FIG. 17B shows a state where data of a dummy pattern is programmed in a dummy memory cell DMC2 adjacent to a main memory cell of a cell string when the post-program mode or the pre-program mode is performed after the erase operation. In other words, data of a dummy pattern may be programmed (P_1′) in the dummy memory cell DMC2 connected to the dummy word line DWL2 adjacent to the main word line WL1 before a program operation is performed for the main word lines WL1 to WLn after the erase operation is performed.

FIG. 17C shows a state P_1 PGM to which a first main memory cell MMC1 of a cell string is programmed after the post-program mode or the pre-program mode is performed. In other words, FIG. 17C shows a state in which after the erase operation is performed, the dummy memory cell DMC2 connected to the dummy word line DWL2 adjacent to the main word line WL1 is programmed through a post-program operation or a pre-program operation, and then, the main memory cell MMC1 connected to the main word line WL1 is programmed.

According to an exemplary embodiment of the inventive concept, a threshold voltage variation of word line-based memory cells in a memory block based on program execution under a condition where the post-program mode or the preprogram mode is enabled is shown in FIG. 18.

Referring to FIG. 18, it may be seen that a threshold voltage variation of a program state P1 of memory cells connected to a dummy word line DWL2 which has been programmed by a post-program operation or a pre-program operation is shifted toward a threshold voltage of an erase state E0 in comparison with a threshold voltage variation of a program state P1 of memory cells connected to main word lines WL1 to WLn (where n is an integer equal to or more than three). Since the dummy word line DWL2 is programmed in a state where adjacent pages are all erased, most of the trapped charges may be used for first programming a page of the dummy word line DWL2 after the erase operation. For this reason, as shown in FIG. 18, the reliability of the memory cells connected to the dummy word line DWL2 is the lowest in the cell string, however, the reliability of the memory cells connected to a first main word line WL1 is enhanced.

In other words, the reliability of the memory cells connected to the main word lines WL1 to WLn is enhanced by performing a program operation on the memory cells connected to the dummy word line DWL2 through a post-program operation or a pre-program operation after the erase operation.

For reference, input data to be programmed may be randomized and then may be programmed in memory cells connected to a main word line. For example, if data of a dummy pattern which is programmed in the dummy word line DWL2 is 0 in all bits, each of the dummy memory cells which are connected to the dummy word line DWL2 through a 2N-time program operation while the main memory cell is being programmed N times may become a worst memory cell. Therefore, data of a dummy pattern which is to be programmed in a dummy word line may be randomly determined.

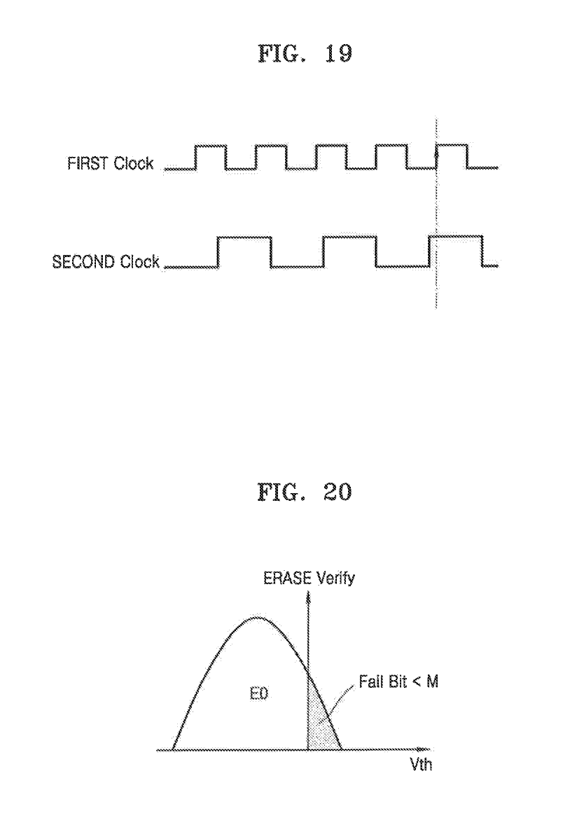

FIG. 19 is a diagram for describing a method of randomly determining data of a dummy pattern used for a post-program operation or a preprogram operation according to an exemplary embodiment of the inventive concept.

Referring to FIG. 19, one data pattern of two candidate data patterns may be determined as data of a dummy pattern, based on a phase which is detected by using two clock signals. For example, the two candidate data patterns may be set as a first candidate data pattern “0101010101 . . . 01” and a second candidate data pattern “10101010 . . . 10”. The two candidate data patterns may be set as mutually inverted data. For example, the candidate data patterns may be stored in the ROM 16A of FIG. 5 or the ROM 16C of FIG. 7. For example, the two clock signals may include a main clock signal and a pump clock signal. Here, the pump clock signal denotes a clock signal used to boost a voltage level.

For example, when a phase of the second clock signal which is detected in a rising edge of the first clock signal at a random or certain timing is high, the first candidate data pattern may be determined as data of a dummy pattern. In addition, when the phase of the second clock signal which is detected in the rising edge of the first clock signal at the random or certain timing is low, the second candidate data pattern may be determined as data of a dummy pattern.

FIG. 20 is a diagram for describing a method of randomly determining data of a dummy pattern used for a post-program operation according to an exemplary embodiment of the inventive concept.

Referring to FIG. 20, one data pattern selected from among two or more candidate data patterns may be determined as data of a dummy pattern, based on information which is generated in a verification process of an erase operation. For example, when the number of fail bits which are detected in an erase verification process is less than an M number that is a reference value, processing may be performed as an erase pass, and in this case, data of a dummy pattern may be determined based on the number of fail bits which are detected in the erase pass. As a detailed example, in a state where two candidate data patterns are set, when the number of fail bits which are detected in the erase pass is an odd number, the first candidate data pattern may be determined as data of a dummy pattern, and when the number of fail bits is an even number, the second candidate data pattern may be determined as the data of the dummy pattern.

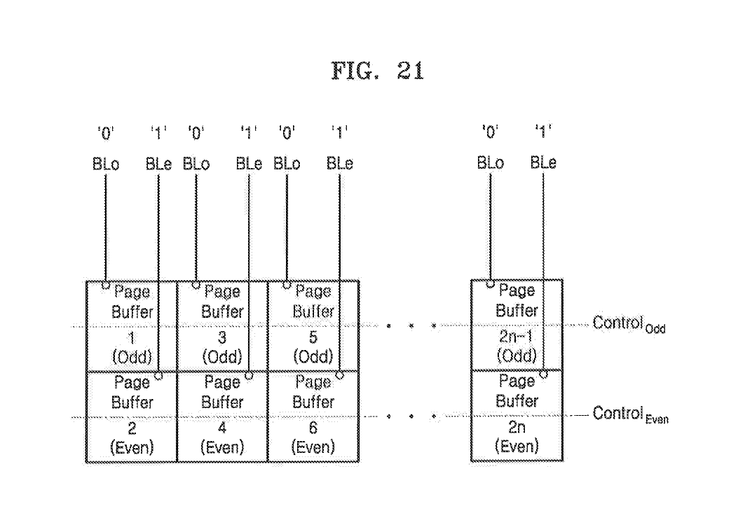

FIG. 21 is a diagram for describing a method of randomly determining data of a dummy pattern used for a post-program operation or a preprogram operation according to an exemplary embodiment of the inventive concept.

Referring to FIG. 21, an even/odd pattern may be randomly generated by using a connection structure of a bit line and the page buffer 15 without using a ROM (for example, 16A of FIG. 5 or 16C of FIG. 7) that stores a plurality of candidate data patterns which is to be used as data of a dummy pattern. For example, as shown in FIG. 19, when a phase which is detected by using two clock signals is high, the page buffer 15 may be controlled to set an odd bit line BLo to 0 and set an even bit line BLe to 1 (as shown in FIG. 21). In this way, when the phase which is detected by using the two clock signals is low, the page buffer 15 may be controlled to set the odd bit line to 1 and set the even bit line to 0. As another example, a value of an odd bit line and a value of an even bit line may be randomly determined based on information which is generated in a verification process of an erase operation. For example, when the number of fail bits which are detected in erase pass is an odd number, the page buffer 15 may be controlled to set an odd bit line to 1 and set an even bit line to 0. In this way, when the number of fail bits which are detected in the erase pass is an even number, the page buffer 15 may be controlled to set the odd bit line BLo to 0 and set the even bit line BLe to 1 (as shown in FIG. 21).

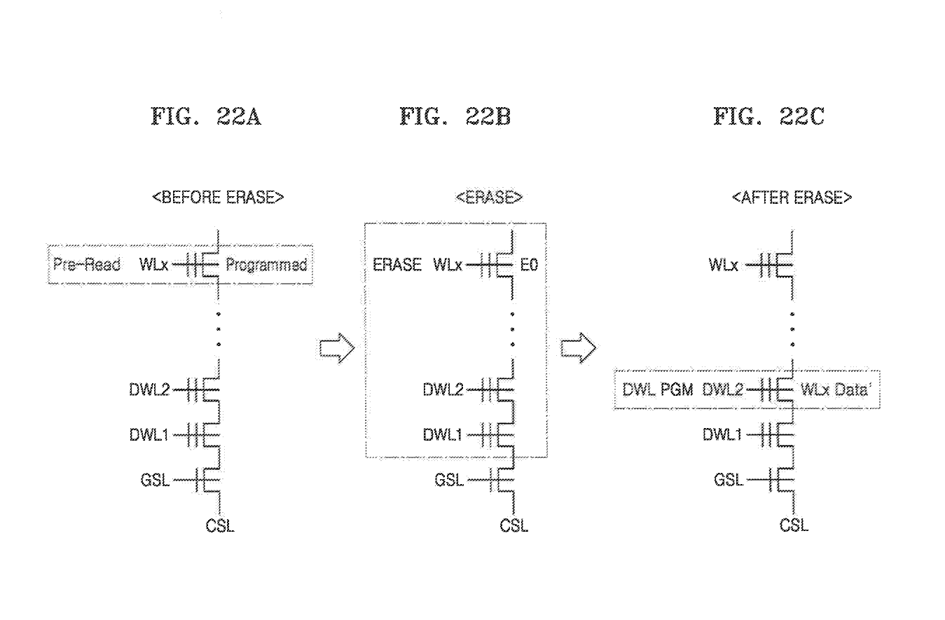

FIG. 22 is a diagram for describing a method of randomly determining data of a dummy pattern used for a post-program operation according to an exemplary embodiment of the inventive concept.

Referring to FIG. 22A, before an erase operation, data of an arbitrary word line WLx may be read and may be backed up to the page buffer 15 or a RAM (for example, 220B of FIG. 13 or 220D of FIG. 14) of a memory controller. After a backup operation, as shown in FIG. 22B, memory cells connected to all word lines including a dummy word line of a memory block to be erased may be erased.

Subsequently, a dummy word line DWL2 may be programmed with a data pattern which is backed up as shown in FIG. 22C. Therefore, data which is stored in the arbitrary word line WLx before the erase operation may be programmed in the dummy word line DWL2.

As another example, to increase randomness of dummy data, data of the arbitrary word line WLx may be read and backed up before the erase operation, and then, data obtained by inverting some of a backed-up data pattern may be used as a dummy data pattern.

Hereinafter, an edge word line management operation of a memory device performed by the post-program manager 12-1A or 21 illustrated in FIG. 1 or 2 or the pre-program manager 12-1C or 22 illustrated in FIG. 3 or 4 will be described with reference to flowcharts of FIGS. 23 to 26.

First, an edge word line management operation of a memory device performed by the post-program manager 12-1A or 21 illustrated in FIG. 1 or 2 will be described with reference to the flowcharts of FIGS. 23 and 24. For convenience of description, the following description will focus on FIG. 1.

FIG. 23 illustrates a flowchart of an edge word line management method of a memory device according to an exemplary embodiment of the inventive concept.

In operation S110, the post-program manager 12-1A may determine whether an erase command is received by the memory device 10A.

When the erase command is received, the memory device 10A may perform an erase operation on a memory block indicated by an address which is received along with the erase command in operation S120.

Subsequently, the post-program manager 12-1A may determine data of a dummy pattern in operation S130. Here, the data of the dummy pattern may be randomly determined. For example, the post-program manager 12-1A may determine one data pattern, selected from among candidate data patterns, as data of a dummy pattern, based on a phase which is detected at a certain time of one or more clocks used in the memory device 10A. As another example, data which is read from an initially set word line of a memory block before the erase operation may be determined as data of a dummy pattern. As another example, data obtained by inverting some of the data which is read from an initially set word line of a memory block before the erase operation may be determined as data of a dummy pattern. As another example, one data pattern selected from two or more candidate data patterns may be determined as data of a dummy pattern, based on information which is generated in a verification process of the erase operation.

Subsequently, the post-program manager 12-1A may perform a post-program operation of writing the data of the dummy pattern, determined in operation S130, in a dummy memory cell adjacent to a main memory cell of a memory block for which the erase operation has been performed in operation S140. For example, the post-program manager 12-1A may perform a program operation of programming the data of the dummy pattern, determined in operation S130, in dummy memory cells connected to the dummy word line DWL2 most adjacent to a main memory cell among the dummy word lines DWL disposed between the ground selection line GSL and the main word lines MWL in the memory block of FIG. 9 or 10.

FIG. 24 illustrates a flowchart of an edge word line management method of a memory device according to an exemplary embodiment of the inventive concept.

In operation S210, the post-program manager 12-1A may determine whether an erase command is received by the memory device 10A.

When the erase command is received, the memory device 10A may perform an erase operation on a memory block indicated by an address which is received along with the erase command in operation S220.

Subsequently, the post-program manager 12-1A may determine whether the post-program mode is enabled in operation S230. For example, when a program/erase cycle count for each memory block is greater than an initially set threshold value, the post-program manager 12-1A may set a corresponding memory block to a post-program mode enable state. As another example, the post-program mode may be set to an enable state in a test process or a user environment.

When it is determined in operation S320 that the post-program mode is enabled, the post-program manager 12-1A may determine data of a dummy pattern in operation S240. The data of the dummy pattern may be randomly determined in various methods described above in operation S140 of FIG. 23.

Subsequently, the post-program manager 12-1A may perform a post-program operation of writing the data of the dummy pattern, determined in operation S240, in a dummy memory cell adjacent to a main memory cell of a memory block for which the erase operation has been performed in operation S250. For example, the post-program manager 12-1A may perform a program operation of programming the data of the dummy pattern, determined in operation S240, in dummy memory cells connected to the dummy word line DWL2 most adjacent to a main memory cell among the dummy word lines DWL disposed between the ground selection line GSL and the main word lines MWL in the memory block of FIG. 9 or 10.

Next, an edge word line management operation of a memory device performed by the pre-program manager 12-1C or 22 illustrated in FIG. 3 or 4 will be described with reference to the flowcharts of FIGS. 25 and 26. For convenience of description, the following description will focus on FIG. 3.

FIG. 25 illustrates a flowchart of an edge word line management method of a memory device according to an exemplary embodiment of the inventive concept.

In operation S310, the pre-program manager 12-1C may determine whether a program command is received by the memory device 10C.

When it is determined in operation S310 that the program command is received, the pre-program manager 12-1C may determine whether the received program command is a first program command of a free memory block in operation S320. Here, the free memory block denotes an empty memory block in which data is not yet written after an erase operation is performed. For example, when a program command for an address corresponding to a word line WL1 in the memory block of FIG. 9 or 10 is received, the received program command may be determined as the first program command of the free memory block. This is because programming is performed in an order from a word line closest to the common source line CSL in a cell string of a flash memory to a word line farther away from the common source line CSL. In other words, first programming of the free memory block may be performed in the main word line WL1 closest to the common source line CSL among word lines except a dummy word line.

When it is determined in operation S320 that the received program command is a first program command of the free memory block, the pre-program manager 12-1C may randomly determine data of a dummy pattern in operation S330. Here, the data of the dummy pattern may be randomly determined. For example, the pre-program manager 12-1C may set at least two candidate data patterns and may determine, as data of a dummy pattern, one data pattern selected from the at least two candidate data patterns, based on a phase which is detected at a certain time of one or more clock signals.

Subsequently, the pre-program manager 12-1C may perform a pre-program operation of writing the data of the dummy pattern, determined in operation S330, in a dummy memory cell adjacent to a main memory cell of the free memory block in operation S340. For this case, assume the free memory block where the program command received in operation S310 is to be executed is as illustrated in FIG. 9 or 10. Thus, for example, the pre-program manager 12-1C may perform a program operation of programming the data of the dummy pattern in dummy memory cells connected to the dummy word line DWL2 most adjacent to a main memory cell among the dummy word lines DWL disposed between the ground selection line GSL and the main word lines MWL.

When it is determined in operation S320 that the received program command is a first program command of the free memory block, after the pre-program operation is performed in operation S340, the memory device 10C may execute the received program command in operation S350. For example, the pre-program manager 12-1C may perform an operation of pre-programming data of a dummy pattern in the dummy memory cells connected to the dummy word line DWL2 in the memory block of FIG. 9 or 10, and then, may perform an operation of programming data in the memory cells connected to the word line WL1 along with the program command.

FIG. 26 illustrates a flowchart of an edge word line management method of a memory device according to an exemplary embodiment of the inventive concept.

In operation S410, the pre-program manager 12-1C may determine whether a program command is received by the memory device 10C.

When it is determined in operation S410 that the program command is received, the pre-program manager 12-1C may determine whether the pre-program mode is enabled in operation S420. For example, when a program/erase cycle count for each memory block is greater than an initially set threshold value, the pre-program manager 12-1C may set a corresponding memory block to a pre-program mode enable state. As another example, the pre-program mode may be set to an enable state in a test process or a user environment.

When it is determined in operation S420 that the pre-program mode is enabled, the pre-program manager 12-1C may determine whether the program command received in operation S410 is a first program command of a free memory block in operation S430.

When it is determined in operation S430 that the received program command is the first program command of the free memory block, the pre-program manager 12-1C may determine data of a dummy pattern in operation S440. For example, the pre-program manager 12-1C may randomly determine the data of the dummy pattern in the method described above in operation S330.

Subsequently, the pre-program manager 12-1C may perform a pre-program operation of writing the data of the dummy pattern, determined in operation S440, in a dummy memory cell adjacent to a main memory cell of the free memory block in operation S450. For example, if the free memory block where the program command received in operation S410 is to be executed is as illustrated in FIG. 9 or 10, the pre-program manager 12-1C may perform a program operation of programming the data of the dummy pattern in the dummy memory cells connected to the dummy word line DWL2.

When the pre-program mode is disabled as a determination result of operation S420 or the received program command is not the first program command of the free memory block as a determination result of operation S430, after the pre-program operation is performed in operation S450, the memory device 10C may execute the received program command in operation S460. For example, the pre-program manager 12-1C may perform an operation of pre-programming data of a dummy pattern in the dummy memory cells connected to the dummy word line DWL2 in the memory block of FIG. 9 or 10, and then, may perform an operation of programming data in the memory cells connected to the word line WL1 along with the program command.

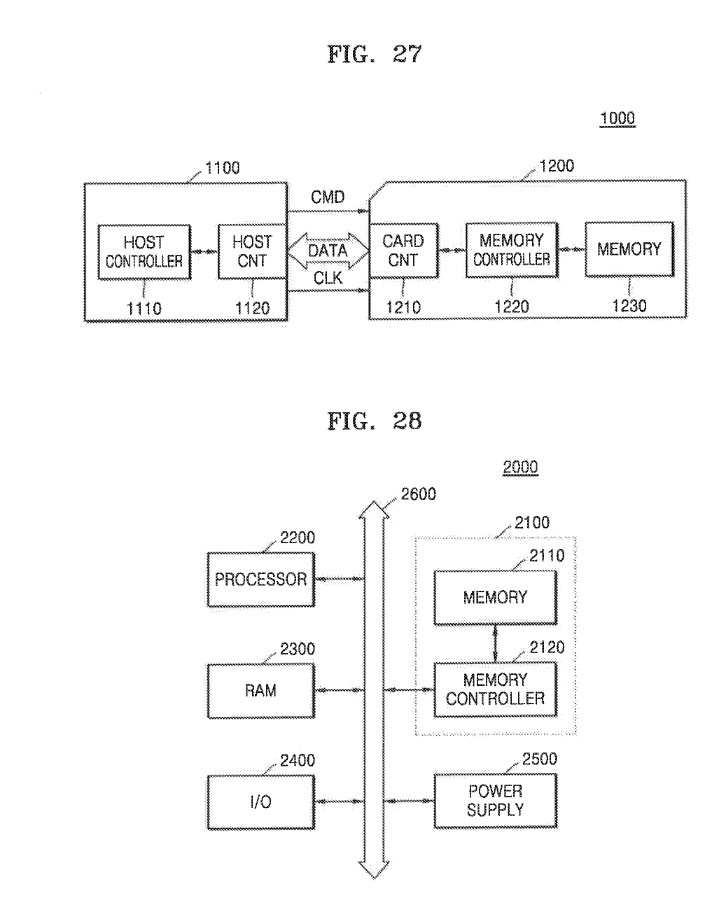

FIG. 27 is a block diagram illustrating a memory system according to an exemplary embodiment of the inventive concept being applied to a memory card system 1000.

Referring to FIG. 27, the memory card system 1000 may include a host 1100 and a memory card 1200. The host 1100 may include a host controller 1110 and a host connector 1120. The memory card 1200 may include a card connector 1210, a memory controller 1220, and a memory device 1230. The memory controller 1220 and the memory device 1230 may respectively use the memory controller 20A to 20D and the memory device 10A to 10D illustrated in FIGS. 1 to 4.

The host 1100 may write data in the memory card 1200 or may read data stored in the memory card 1200. The host controller 1110 may transmit a command CMD, a clock signal CLK generated by a clock generator included in the host 1100, and data DATA to the memory card 1200 through the host connector 1120.

The memory controller 1220 may store data in the memory device 1230 in synchronization with a clock signal generated by a clock generator included in the memory controller 1220, in response to a command received through the card connector 1210. The memory device 1230 may store data transmitted from the host 1100.

The memory card 1200 may be implemented with a compact flash card (CFC), a Microdrive, a smart media card (SMC), a multimedia card (MMC), a security digital card (SDC), a memory stick, a universal serial bus (USB) flash memory driver, and/or the like.

FIG. 28 is a block diagram illustrating a computing system 2000 including a memory system according to an exemplary embodiment of the inventive concept.

Referring to FIG. 28, the computing system 2000 may include a memory system 2100, a processor 2200, a RAM 2300, an input/output (I/O) device 2400, and a power supply 2500.

The memory system 2100 may include a memory device 2110 and a memory controller 2120. The memory controller 2120 and memory device 2110 may respectively use the memory controller 20A to 20D and the memory device 10A to 10D illustrated in FIGS. 1 to 4.

The computing system 2000 may further include a plurality of ports that communicate with a video card, a sound card, a memory card, and a USB device or communicate with other electronic devices. The computing system 2000 may be implemented with a personal computer (PC) or may be implemented with a portable electronic device such as a notebook computer, a portable phone, a personal digital assistant (PDA), a camera, or the like.

The processor 2200 may perform certain calculations or tasks. According to an exemplary embodiment of the inventive concept, the processor 2200 may be a microprocessor or a CPU. The processor 2200 may communicate with the RAM 2300, the I/O device 2400, and the memory system 2100 through a bus 2600 such as an address bus, a control bus, a data bus, or the like. According to an exemplary embodiment of the inventive concept, the processor 2200 may be connected to an extension bus such as a peripheral component interconnect (PCI) bus.

The RAM 2300 may store data used for an operation of the computing system 2000. For example, the RAM 2300 may be implemented with a dynamic RAM (DRAM), a mobile DRAM, a static RAM (SRAM), a phase-change RAM (PRAM), a ferroelectric RAM (FRAM), a resistive RAM (RRAM), and/or a magnetoresistive RAM (MRAM).

The I/O device 2400 may include an input unit, such as a keyboard, a keypad, a mouse, or the like, and an output unit such as a display or the like. The power supply 2500 may supply an operation voltage used for an operation of the computing system 2000.

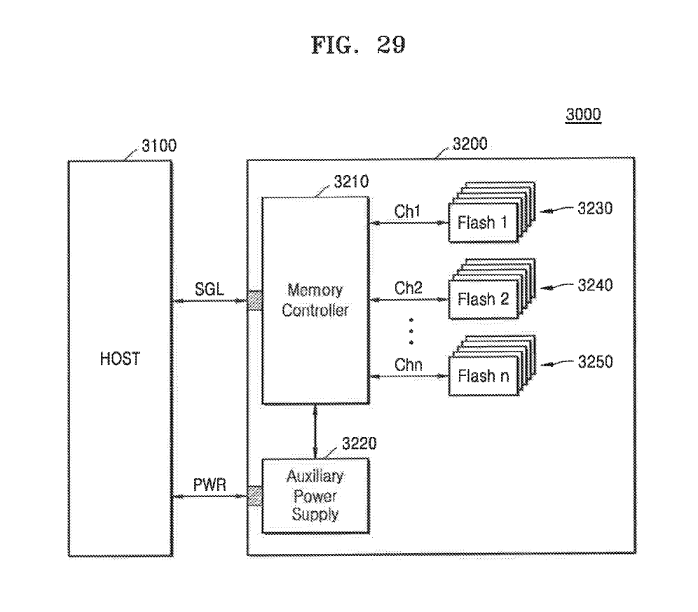

FIG. 29 is a block diagram illustrating a memory system according to an exemplary embodiment of the inventive concept being applied to a solid state disk (SSD) system 3000.

Referring to FIG. 29, the SSD system 3000 may include a host 3100 and an SSD 3200. The SSD 3200 may transmit or receive a signal SGL to or from the host 3100 through a signal connector and may receive power PWR through a power connector. The SSD 3200 may include a memory controller 3210, an auxiliary power supply 3220, and a plurality of memory devices 3230, 3240 and 3250. The memory controller 3210 and the plurality of memory devices 3230, 3240 and 3250 may respectively use the memory controller 20A to 20D and the memory device 10A to 10D illustrated in FIGS. 1 to 4. The memory controller 3210 and the plurality of memory devices 3230, 3240 and 3250 may be connected via a plurality of channels Ch1 to Chn.

Exemplary embodiments of the inventive concept may be implemented as a method, a device, a system, or the like. When an exemplary embodiment of the inventive concept is implemented as software, elements according to the present embodiment may be code segments for performing operations. Programs or code segments may be stored in a processor-readable medium. The processor-readable medium may include all mediums for storing information. Examples of the processor-readable medium may include an electronic circuit, a semiconductor memory device, a ROM, flash memory, an erasable ROM (EROM), a floppy disk, an optical disk, a hard disk, and/or the like.

Exemplary embodiments of the inventive concept provide a memory device and an edge word line management method thereof which equalize bit error rate of pages in the memory device, for example.

While the inventive concept has been particularly shown and described with reference to exemplary embodiments thereof, it will be understood that various changes in form and details may be made therein without departing from the spirit and scope of the inventive concept as defined by the following claims.

What is claimed is:

1. An edge word line management method of a memory device, comprising:
performing an erase operation on a memory device in response to an erase command;
randomly determining data of a dummy pattern; and
performing a post-program operation by writing the data of the dummy pattern in a dummy memory cell, wherein the dummy memory cell is adjacent to a main memory cell of a cell string included in a memory block for which the erase operation has been performed.

2. The edge word line management method of claim 1, wherein the dummy memory cell is disposed between the main memory cell and a ground selection transistor of the cell string.

3. The edge word line management method of claim 1, wherein when a plurality of dummy memory cells are disposed between the main memory cell and a ground selection transistor of the cell string included in the memory block, data of the dummy pattern is written in a dummy memory cell closest to the main memory cell.

4. The edge word line management method of claim 1, wherein randomly determining data of a dummy pattern comprises: determining the data of the dummy pattern as data which is read from an initially set word line of the memory block and backed up before the erase operation.

5. The edge word line management method of claim 1, wherein randomly determining data of a dummy pattern comprises: determining the data of the dummy pattern as data obtained by inverting some data which is read from an initially set word line of the memory block before the erase operation.

6. The edge word line management method of claim 1, wherein randomly determining data of a dummy pattern comprises: determining the data of the dummy pattern as one data pattern selected from two or more candidate data patterns by using information generated in a verification process of the erase operation.

7. The edge word line management method of claim 1, wherein randomly determining data of a dummy pattern comprises:
setting at least two candidate data patterns; and
determining the data of the dummy pattern as one data pattern selected from the at least two candidate data patterns, based on a phase which is detected at a certain time of one or more clock signals used in the memory device.

8. The edge word line management method of claim 1, wherein randomly determining data of a dummy pattern comprises: determining the data of the dummy pattern as an even or odd bit line pattern which is randomly set based on a phase detected at a certain time of one or more clock signals used in the memory device by using a connection structure of a bit line and a page buffer.

9. The edge word line management method of claim 1, further comprising: checking a set state of a post-program mode,
wherein
when the post-program mode is enabled, a post-program operation is performed, and
when the post-program mode is disabled, the post-program operation is not performed.

10. The edge word line management method of claim 9, further comprising: when a program or erase cycle count for each of a plurality of memory blocks is greater than an initially set threshold value, setting a corresponding memory block to a post-program mode enable state.

11. An edge word line management method of a memory device, comprising:
randomly determining data of a dummy pattern in response to a program command for performing a first program operation on a free memory block of the memory device;
performing a pre-program operation by writing the data of the dummy pattern in a dummy memory cell, wherein the dummy memory cell is adjacent to a main memory cell of a cell string included in the free memory block; and
performing a program operation in response to the program command on the main memory cell after the pre-program operation is performed.

12. The edge word line management method of claim 11, wherein the dummy memory cell is disposed between the main memory cell and a ground selection transistor of the cell string included in the free memory block.

13. The edge word line management method of claim 11, wherein randomly determining data of a dummy pattern comprises: determining the data of the dummy pattern as one data pattern selected from at least two candidate data patterns, based on a phase which is detected at a certain time of one or more clock signals.

14. The edge word line management method of claim 11, further comprising:
checking a set state of a pre-program mode,
wherein
when the pre-program mode is enabled, the pre-program operation is performed, and
when the pre-program mode is disabled, the pre-program operation is not performed.

15. The edge word line management method of claim 14, further comprising: when a program or erase cycle count for each of a plurality of memory blocks is greater than an initially set threshold value, setting a corresponding memory block to a pre-program mode enable state.

16. A method of operating a memory device, comprising:
performing an erase operation on a cell string of the memory device, wherein the cell string includes dummy memory cells and main memory cells;
programming data of a dummy pattern in a first dummy memory cell, wherein the first dummy memory cell is adjacent to a first main memory cell; and
programming the first main memory cell after the first dummy memory cell is programmed.

17. The method of claim 16, wherein a program management circuit determines the data of the dummy pattern, and wherein the program management circuit is included in the memory device or a memory controller.

18. The method of claim 16, wherein the data of the dummy pattern is random data.

19. The method of claim 16, wherein the first dummy memory cell is disposed between the first main memory cell and a ground select transistor of the cell string.

20. The method of claim 16, wherein the dummy memory cells and the main memory cells are vertically stacked on each other in the cell string.
